(19) United States
(12) Patent Application Publication
(10) Pub. No.: US 2023/0416442 A1
(43) Pub. Date: Dec. 28, 2023

(54) PROTECTIVE LAYER AND FOLDABLE DEVICE

(71) Applicant: FUJIFILM Corporation, Tokyo (JP)

(72) Inventors: Ayako MATSUMOTO, Kanagawa (JP); Nobuyuki AKUTAGAWA, Kanagawa (JP); Yuta FUKUSHIMA, Kanagawa (JP); Tetsu KITAMURA, Kanagawa (JP)

(73) Assignee: FUJIFILM Corporation, Tokyo (JP)

(21) Appl. No.: 18/467,450

(22) Filed: Sep. 14, 2023

Related U.S. Application Data
(63) Continuation of application No. PCT/JP2022/012087, filed on Mar. 16, 2022.

(30) Foreign Application Priority Data
Mar. 31, 2021 (JP) 2021-062153
Dec. 17, 2021 (JP) 2021-205521

(51) Int. Cl. C08F 290/14; C09J 7/24; C08J 7/046; C08J 5/18; C03C 17/32; C03C 17/34

(52) U.S. Cl. CPC C08F 290/148; C09J 7/24; C08J 7/046; C08J 5/18; C03C 17/32; C03C 17/3405; C08J 2351/08; C09J 2451/001; C03C 2217/78

(57) ABSTRACT

A protective layer to be used in a foldable device having a cover window containing glass, contains: at least one of the following (A), (B), or (C), wherein (A) is a polymerized substance of a polymerizable compound which has one or more hydrogen bonding group and three or more (meth)acryloyl groups in a molecule of the polymerizable compound, in which a hydrogen-bonding proton value is 3.5 mol/kg or more and a (meth)acryloyl value is 4.8 mol/kg or more, (B) is a compound including a metal coordinate bond, and (C) is a compound including a host-guest binding.

### CROSS REFERENCE TO RELATED APPLICATION

This is a continuation of International Application No. PCT/JP2022/012087 filed on Mar. 16, 2022, and claims priority from Japanese Patent Application No. 2021-062153 filed on Mar. 31, 2021, and Japanese Patent Application No. 2021-205521 filed on Dec. 17, 2021, the entire disclosures of which are incorporated herein by reference.

### BACKGROUND OF THE INVENTION

### 1. Field of the Invention

The present invention relates to a protective layer and a foldable device. More specifically, the present invention relates to a protective layer which is provided on a surface of a cover window in a foldable device having a cover window made of glass, and a foldable device including the protective layer.

### 2. Description of the Related Art

In recent years, for example, a bendable device (foldable device) has been developed as a device such as a smartphone. For example, since a display such as a liquid crystal display device (LCD) and an electroluminescent display (ELD) in the foldable device can be bended, folded, or rolled, the foldable device is expected to be applied to various uses such as smartphones, mobile phones, tablet PCs, navigation systems, electronic books, televisions, and monitors.

In the related art, from the viewpoint of bend resistance, a cover window provided on a front surface (surface on which an image is displayed) of the foldable device has been made of resin, but in recent years, a cover window made of glass has also been proposed (for example, refer to JP2018-24567A, JP2019-532356A, JP2010-280098A, JP2017-171571A, and JP2011-82070A).

### SUMMARY OF THE INVENTION

As the cover window made of glass used for the foldable device, chemically strengthened glass is typically used, but since a thin chemically strengthened glass may break simply, a protective layer is usually provided on the surface from the viewpoint of scattering prevention.

However, in a case where the protective layer in the related art is provided on the cover window made of glass, there is a problem that surface smoothness and hardness, which are advantages of the cover window made of glass, are impaired.

An object of the present invention is to provide a protective layer which can be used for a foldable device having a cover window made of glass and has excellent smoothness, pencil hardness, and anti-scattering properties, and a foldable device including the protective layer.

As a result of intensive studies, the present inventors have found that the above-described objects can be achieved by the following methods.

<1>

A protective layer to be used in a foldable device having a cover window made of glass, the protective layer comprising:
at least one of the following (A), (B), or (C),
(A) a polymerized substance of a polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more,

(B) a compound including a metal coordinate bond,

(C) a compound including a host-guest binding.

<2>

The protective layer according to <1>,
in which an elastic modulus of the protective layer is 6 GPa or more, and
a breaking elongation of the protective layer is 10% or more.

<3>

The protective layer according to <2>,
in which the breaking elongation of the protective layer is 23% or more.

<4>

The protective layer according to any one of <1> to <3>,
in which a thickness of the cover window is 100 μm or less.

<5>

The protective layer according to any one of <1> to <4>,
in which the protective layer contains (A), and
the hydrogen bonding group in (A) is at least one selected from the group consisting of a hydroxy group, a carboxy group, a urethane group, an amino group, an amide group, a urea group, a boronic acid group, a thiourethane group, a thioamide group, and a thiourea group.

<6>

The protective layer according to any one of <1> to <5>,
in which a thickness of the protective layer is 10 μm or less.

<7>

The protective layer according to any one of <1> to <6>,
in which a pressure-sensitive adhesive layer or an adhesive layer having a thickness of 1 μm or less is provided on at least one surface of the protective layer.

<8>

The protective layer according to any one of <1> to <7>,
in which a scratch resistant layer is provided on at least one surface of the protective layer.

<9>

The protective layer according to <8>,
in which the scratch resistant layer contains at least one of the following (A), (B), or (C),
(A) a polymerized substance of a polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more,
(B) a compound including a metal coordinate bond,
(C) a compound including a host-guest binding.

<10>

A foldable device comprising:
a cover window made of glass; and
a protective layer provided on the cover window,
in which the protective layer is the protective layer according to any one of <1> to <6>.

<11>

The foldable device according to <10>,
in which a thickness of the cover window is 100 μm or less.

<12>

The foldable device according to <10> or <11>,
in which a pressure-sensitive adhesive layer or an adhesive layer having a thickness of 1 μm or less is provided between the protective layer and the cover window.

<13>

The foldable device according to any one of <10> to <12>,
in which a scratch resistant layer is provided on a surface of the protective layer opposite to the cover window side.

<14>

The foldable device according to <13>,
in which the scratch resistant layer contains at least one of the following (A), (B), or (C),
(A) a polymerized substance of a polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more,
(B) a compound including a metal coordinate bond,
(C) a compound including a host-guest binding.

According to the present invention, it is possible to provide a protective layer which can be used for a foldable device having a cover window made of glass and has excellent smoothness, pencil hardness, and anti-scattering properties, and a foldable device including the protective layer.

### BRIEF DESCRIPTION OF THE DRAWINGS

FIG. 1 is a schematic diagram of samples of Examples 1 to 9, 15, and 16, and Comparative Examples 4 and 5.

FIG. 2 is a schematic diagram of samples of Examples 10 to 12.

FIG. 3 is a schematic diagram of samples of Examples 13 and 14.

FIG. 4 is a schematic diagram of a sample of Comparative Example 1.

FIG. 5 is a schematic diagram of samples of Comparative Examples 2 and 3.

### DESCRIPTION OF THE PREFERRED EMBODIMENTS

Hereinafter, embodiments of the present invention will be specifically described, but the present invention is not limited thereto. In the present specification, in a case where numerical values represent a value of physical properties, a value of characteristics, and the like, a description of “(numerical value 1) to (numerical value 2)” means “(numerical value 1) or more and (numerical value 2) or less”. In addition, in the present specification, a description of “(meth)acrylate” means “at least one of acrylate or methacrylate”. The same will be applied to “(meth)acrylic acid”, “(meth)acryloyl”, “(meth)acrylamide”, “(meth)acryloyloxy”, and the like. “(Meth)acryloyl group” represents the meaning of “at least one of an acryloyl group or a methacryloyl group”. “(Meth)acryloyl value” represents the meaning of “at least one of an acryloyl value or a methacryloyl value”.

[Protective Layer]

The protective layer according to the embodiment of the present invention is a protective layer to be used in a foldable device having a cover window made of glass, the protective layer containing
at least one of the following (A), (B), or (C).
(A) a polymerized substance of a polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more
(B) a compound including a metal coordinate bond
(C) a compound including a host-guest binding

The protective layer according to the embodiment of the present invention contains at least any one of (A), (B), or (C) above.

Hereinafter, each of (A) to (C) will be described.

[(A)]
(A) is a polymerized substance of a polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more.

Hereinafter, the “polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more” is also referred to as “polymerizable compound (a1)”.

<Polymerizable Compound (a1)>

The polymerizable compound (a1) is a polymerizable compound which has one or more hydrogen bonding groups and three or more (meth)acryloyl groups in a molecule, in which a hydrogen-bonding proton value is 3.5 mol/kg or more and a (meth)acryloyl value is 4.8 mol/kg or more.

Hereinafter, the polymerizable compound (a1) will be described.

(Hydrogen Bonding Group)

The polymerizable compound (a1) has one or more hydrogen bonding groups in the molecule.

The hydrogen bonding group is a group including a hydrogen atom (proton) capable of forming a hydrogen bond. The hydrogen atom capable of forming a hydrogen bond is a hydrogen atom which is covalently bonded to an atom having a high degree of electrical negativeness, and can form a hydrogen atom with a nitrogen atom, an oxygen atom, or the like located in the vicinity thereof.

The hydrogen bonding group included in the polymerizable compound (a1) is not particularly limited, and may be a generally known hydrogen bonding group.

As the hydrogen bonding group included in the polymerizable compound (a1), at least one selected from the group consisting of a hydroxy group, a carboxy group, a urethane group, an amino group, an amide group, a urea group, a boronic acid group, a thiourethane group, a thioamide group, and a thiourea group is preferable; at least one selected from the group consisting of a urethane group, a thiourethane group, a urea group, a thiourea group, an amide group, and a thioamide group is more preferable; at least one selected from the group consisting of a urethane group, a urea group, and an amide group is still more preferable; and a urea group is particularly preferable.

In the present invention, the amide group is a divalent linking group represented by —NH—C(═O)—, the urethane group is a divalent linking group represented by —NH—C(═O)—O—, the urea group is a divalent linking group represented by —NH—C(═O)—NH—, the thiourethane group is a divalent linking group represented by —NH—C(═S)—O—, the thiourea group is a divalent linking group represented by —NH—C(═S)—NH—, and the thioamide group is a divalent linking group represented by —NH—C(═S)—.

(Hydrogen-Bonding Proton Value)

The hydrogen-bonding proton value of the polymerizable compound (a1) is 3.5 mol/kg or more.

The hydrogen-bonding proton value represents a density of hydrogen atoms (protons) capable of forming a hydrogen atom in the compound, and is calculated from the following expression (i).

Hydrogen-bonding proton value=Substance amount of hydrogen atom (proton) capable of forming hydrogen bond in one molecule of compound (mol)/Mass of one molecule of compound (kg) (i)

The number of hydrogen atoms capable of forming a hydrogen bond, which are included in the amide group and the thioamide group, is 1, the number of hydrogen atoms capable of forming a hydrogen bond, which are included in the urethane group and the thiourethane group, is 1, and the number of hydrogen atoms capable of forming a hydrogen bond, which are included in the urea group and the thiourea group, is 2.

In a case where the polymerizable compound (a1) is a polymer having a constitutional unit, a method of obtaining the hydrogen-bonding proton value is as follows.

The constitutional unit is a repeating unit, and for example, in a case where the polymerizable compound (a1) is a polymer obtained by polymerizing only one kind of monomer, the constitutional unit included in the polymerizable compound (a1) is one kind, and in a case of a copolymer of two kinds of monomers, the constitutional unit is two kinds.

In a case where the polymerizable compound (a1) has one kind of constitutional unit, the hydrogen-bonding proton value of the polymerizable compound (a1) is a hydrogen-bonding value of one constitutional unit calculated by the expression (i) described above.

In a case where the polymerizable compound (a1) has a plurality of kinds of constitutional units, a sum of values (molar fraction average value), which is obtained by multiplying the hydrogen-bonding proton value of each constitutional unit calculated by the expression (i) described above by a compositional ratio (% by mole) of each constitutional unit in the polymerizable compound (a1), and then dividing each value by 100, is defined as the hydrogen-bonding proton value of the polymerizable compound (a1).

Specifically, in a case where the polymerizable compound (a1) has two kinds of constitutional units (constitutional unit 1 and constitutional unit 2), the hydrogen-bonding proton value of the polymerizable compound (a1) is calculated by the following expression (iiA).

Hydrogen-bonding proton value=H₁ (hydrogen-bonding proton value of constitutional unit 1)×W₁ (compositional ratio of compositional ratio 1 (% by mole))/100+H₂ (hydrogen-bonding proton value of constitutional unit 2)×W₂ (compositional ratio of compositional ratio 2 (% by mole))/100 (iiA)

In addition, in a case where the polymerizable compound (a1) has a constitutional unit 1, a constitutional unit 2, . . . , and a constitutional unit X (X represents an integer of 3 or more), the hydrogen-bonding proton value of the polymerizable compound (a1) is calculated by the following expression (iiB).

Hydrogen-bonding proton value=H₁ (hydrogen-bonding proton value of constitutional unit 1)×W₁ (compositional ratio of compositional ratio 1 (% by mole))/100+H₂ (hydrogen-bonding proton value of constitutional unit 2)×W₂ (compositional ratio of compositional ratio 2 (% by mole))/100+ . . . +H_{X} (hydrogen-bonding proton value of constitutional unit X)×W_{X} (compositional ratio of compositional ratio×(% by mole))/100 (iiB)

The hydrogen-bonding proton value in the polymerizable compound (a1) is 3.5 mol/kg or more. As a result, since it is possible to increase a density of hydrogen bonds formed by the polymerizable compound (a1), it is presumed that a hardness (pencil hardness) of the surface of the protective layer containing the polymerized substance of the polymerizable compound (a1) can be increased. In addition, since the hydrogen bond can be reversibly dissociated and reformed, it is presumed that stress during strain can be released by the dissociation of the hydrogen bond, and the reformation of the hydrogen bond after structural change can impart bend resistance to the protective layer. In addition, since the reversible dissociation and reformation can occur in a case where an impact force is applied, it is presumed that the protective layer absorbs the force in a thickness direction, and disperses the force in a plane direction, so that anti-scattering properties can be imparted.

The hydrogen-bonding proton value in the polymerizable compound (a1) is 3.5 mol/kg or more, and preferably 4.0 mol/kg or more, more preferably 5.0 mol/kg or more, and still more preferably 6.0 mol/kg or more.

In addition, from the viewpoint of improving solubility and suppressing generation of aggregates during film formation, the hydrogen-bonding proton value in the polymerizable compound (a1) is preferably 20.0 mol/kg or less, more preferably 17.5 mol/kg or less, still more preferably 15.0 mol/kg or less, and even more preferably 12.5 mol/kg or less.

((Meth)Acryloyl Value)

The polymerizable compound (a1) has three or more (meth)acryloyl groups in the molecule. That is, in the molecule, the polymerizable compound (a1) has at least three of groups (group represented by General Formula (T)) selected from the group consisting of an acrylic group (acryloyl group) and a methacrylic group (methacryloyl group).

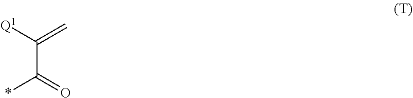

In General Formula (T), Q¹ represents a hydrogen atom or a methyl group, and * represents a bonding position.

In a case where Q₁ is a hydrogen atom, General Formula (T) is an acryloyl group, and in a case where Q¹ is a methyl group, General Formula (T) is a methacryloyl group.

In General Formula (T), * represents a bonding position, but the type of an atom bonded to * is not particularly limited. For example, in a case of bonding * with an oxygen atom, the group represented by General Formula (T) including the oxygen atom is a (meth)acryloyloxy group. In addition, in a case of bonding * with a nitrogen atom (nitrogen atom bonded to a hydrogen atom or a substituent), the group represented by General Formula (T) including the nitrogen atom is a (meth)acryloylamino group ((meth)acrylamide group).

The (meth)acrylamide group includes an amide group, and also corresponds to the hydrogen bonding group.

The (meth)acryloyl value represents a density of (meth)acryloyl groups in the compound, and is calculated by the following expression (iii).

(Meth)acryloyl value=Substance amount of (meth)acryloyl groups in one molecule of compound (mol)/Mass of one molecule of compound (kg) (iii)

In a case where the polymerizable compound (a1) is a polymer having a constitutional unit, a method of obtaining the (meth)acryloyl value is as follows.

In a case where the polymerizable compound (a1) is a polymer having one kind of constitutional unit, the (meth)acryloyl value of the polymerizable compound (a1) is a (meth)acryloyl value calculated with one constitutional unit.

In a case where the polymerizable compound (a1) has a plurality of kinds of constitutional units, a sum of values (molar fraction average value), which is obtained by multiplying the (meth)acryloyl value of each constitutional unit calculated by the expression (iii) described above by a compositional ratio (% by mole) of each constitutional unit in the polymerizable compound (a1), and then dividing each value by 100, is defined as the (meth)acryloyl value of the polymerizable compound (a1).

Specifically, in a case where the polymerizable compound (a1) has two kinds of constitutional units (constitutional unit 1 and constitutional unit 2), the (meth)acryloyl value of the polymerizable compound (a1) is calculated by the following expression (ivA).

(Meth)acryloyl value=C₁ ((meth)acryloyl value of constitutional unit 1)×W₁ (compositional ratio of compositional ratio 1 (% by mole))/100+C₂ ((meth)acryloyl value of constitutional unit 2)×W2 (compositional ratio of compositional ratio 2 (% by mole))/100 (ivA)

In addition, in a case where the polymerizable compound (a1) has a constitutional unit 1, a constitutional unit 2, . . . , and a constitutional unit X (X represents an integer of 3 or more), the (meth)acryloyl value of the polymerizable compound (a1) is calculated by the following expression (ivB).

(Meth)acryloyl value=C₁ ((meth)acryloyl value of constitutional unit 1)×W₁ (compositional ratio of compositional ratio 1 (% by mole))/100+C₂ ((meth)acryloyl value of constitutional unit 2)×W₂ (compositional ratio of compositional ratio 2 (% by mole))/100++Cₓ ((meth)acryloyl value of constitutional unit X)×W_{X} (compositional ratio of compositional ratio X (% by mole))/100 (ivB)

The (meth)acryloyl value of the polymerizable compound (a1) is 4.8 mol/kg or more, and preferably 5.0 mol/kg or more and more preferably 5.4 mol/kg or more.

For the (meth)acryloyl value of the polymerizable compound (a1), a sample is dissolved in an appropriate solvent, an ene-thiol reaction is performed by adding a certain amount of thiol which quantitatively reacts with (meth)acryloyl groups, and then it is possible to estimate the (meth)acryloyl value from the amount of thiol consumed in the reaction. The amount of thiol consumed can be quantified by Nuclear Magnetic Resonance (NMR) or Gas Chromatograph (GC).

The number of (meth)acryloyl groups included in the polymerizable compound (a1) is preferably 3 to 20, more preferably 3 to 12, and still more preferably 3 to 8.

(Sum of Hydrogen-Bonding Proton Value and (Meth)Acryloyl Value)

The sum of the hydrogen-bonding proton value and the (meth)acryloyl value of the polymerizable compound (a1) is not particularly limited, but is preferably 10.5 mol/kg or more, more preferably 11.0 mol/kg or more, still more preferably 11.5 mol/kg or more, and particularly preferably 12.0 mol/kg or more. In a case where the sum of the hydrogen-bonding proton value and the (meth)acryloyl value of the polymerizable compound (a1) is 10.5 mol/kg or more, the surface has higher hardness, which is preferable.

(Ratio of Hydrogen-Bonding Proton Value and (Meth)Acryloyl Value)

A ratio of the hydrogen-bonding proton value and the (meth)acryloyl value of the polymerizable compound (a1) is not particularly limited, but a hydrogen-bonding proton value/(meth)acryloyl value is preferably 0.25 or more and 4.0 or less, more preferably 0.35 or more and 3.5 or less, still more preferably 0.45 or more and 3.0 or less, particularly preferably or more and 2.5 or less, and most preferably 0.60 or more and 2.0 or less. In a case of being the above-described range, the bend resistance and the scattering prevention are improved, which is preferable.

(Molecular Weight)

A molecular weight of the polymerizable compound (a1) is not particularly limited, but is preferably 2,000 or less, more preferably 1,500 or less, still more preferably 1,250 or less, and particularly preferably 1,000 or less.

(Structure of Polymerizable Compound (a1))

A structure of the polymerizable compound (a1) is not particularly limited, but is preferably a compound represented by General Formula (1) or (2).

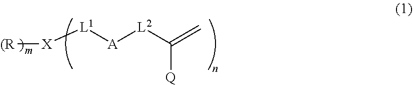

In General Formula (1), R represents a substituent, X represents C or N, L¹ and L² each independently represent a single bond or a divalent linking group, A represents a hydrogen bonding group, Q represents a hydrogen atom or a methyl group, m represents an integer of 0 to 2, and n represents an integer of 2 to 4. However, in a case where X represents C, the sum of m and n is 4, and in a case where X represents N, the sum of m and n is 3. In a case where m represents 2, two R's may be the same as or different from each other. A plurality of L¹'s, A's, L²'s, or Q's may be the same or different from each other.

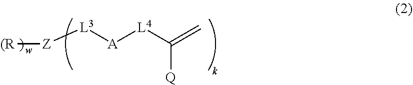

In General Formula (2), Z represents a (k+w)-valent linking group, L³ and L⁴ each independently represent a single bond or a divalent linking group, A represents a hydrogen bonding group, Q represents a hydrogen atom or a methyl group, R represents a substituent, k represents an integer of 2 to 8, and w represents an integer of 0 to 2. A plurality of L³'s, A's, L⁴’ s, or Q's may be the same or different from each other. In a case where w represents 2, two R's may be the same as or different from each other.

In General Formula (1), the substituent represented by R is not particularly limited, and examples thereof include an alkyl group (for example, having 1 to 10 carbon atoms), an aryl group (for example, having 6 to 20 carbon atoms), a cycloalkyl group (for example, having 3 to 10 carbon atoms), an alkenyl group (for example, having 2 to 10 carbon atoms), an alkynyl group (for example, having 2 to 10 carbon atoms), a halogen atom, an alkyloxy group (for example, having 1 to 10 carbon atoms), an aryloxy group (for example, having 6 to 20 carbon atoms), an alkyloxycarbonyl group (for example, having 2 to 10 carbon atoms), an aryloxycarbonyl group (for example, having 7 to 20 carbon atoms), an alkylcarbonyloxy group (for example, having 2 to 10 carbon atoms), an arylcarbonyloxy group (for example, having 7 to 20 carbon atoms), a heterocyclic group (for example, having 2 to 10 carbon atoms), a hydroxy group, a cyano group, and a nitro group.

In General Formula (1), the divalent linking group in a case where L¹ and L² represent a divalent linking group is not particularly limited, and for example, an alkylene group (for example, having 1 to 10 carbon atoms), a cycloalkylene group (for example, having 3 to 10 carbon atoms), an alkenylene group (for example, having 2 to 10 carbon atoms), an arylene group (for example, having 6 to 20 carbon atoms), a divalent heterocyclic group (for example, having 2 to 10 carbon atoms), —O—, —SO₂—, —CO—, —S—, or a divalent linking group obtained by combining a plurality of these groups is preferable. L¹ and L² may have a substituent. The substituent is not particularly limited, and examples thereof include the substituents described as the substituent represented by R in General Formula (1) described above, a (meth)acryloyl group, a (meth)acryloyloxy group, and a (meth)acrylamide group.

In General Formula (1), A represents a hydrogen bonding group, and at least one selected from the group consisting of a urethane group, a thiourethane group, a urea group, a thiourea group, an amide group, and a thioamide group is preferable, at least one selected from the group consisting of a urethane group, a urea group, and an amide group is more preferable, and a urethane group is still more preferable.

In General Formula (1), Q represents a hydrogen atom or a methyl group, and preferably represents a hydrogen atom.

In General Formula (1), m represents an integer of 0 to 2, and preferably represents 0 or 1.

R in General Formula (2) has the same meaning as R in General Formula (1), and specific examples and preferred ranges are also the same.

In General Formula (2), the (k+w)-valent linking group represented by Z is not particularly limited, and a chain-like hydrocarbon group which may have a heteroatom in the chain (for example, having 2 to 10 carbon atoms) or a cyclic hydrocarbon group which may have a heteroatom as a ring member (for example, having 2 to 10 carbon atoms) is preferable. Examples of the above-described heteroatom include an oxygen atom, a nitrogen atom, and a sulfur atom, and an oxygen atom is preferable. A substituent may be bonded to the above-described chain-like hydrocarbon group. A substituent may be bonded to the carbon atom of the ring member of the above-described cyclic hydrocarbon group, or an oxo group (═O) may be bonded to the carbon atom thereof. The above-described substituent is not particularly limited, and examples thereof include the substituents described as the substituent represented by R in General Formula (1) described above, a (meth)acryloyl group, a (meth)acryloyloxy group, and a (meth)acrylamide group.

In General Formula (2), the divalent linking group in a case where L³ and L⁴ represent a divalent linking group is not particularly limited, and for example, an alkylene group (for example, having 1 to 10 carbon atoms), a cycloalkylene group (for example, having 3 to 10 carbon atoms), an alkenylene group (for example, having 2 to 10 carbon atoms), an arylene group (for example, having 6 to 20 carbon atoms), a divalent heterocyclic group (for example, having 2 to 10 carbon atoms), —O—, —SO₂—, —CO—, —S—, or a divalent linking group obtained by combining a plurality of these groups is preferable. L³ and L⁴ may have a substituent. The substituent is not particularly limited, and examples thereof include the substituents described as the substituent represented by R in General Formula (1) described above, a (meth)acryloyl group, a (meth)acryloyloxy group, and a (meth)acrylamide group.

In General Formula (2), A represents a hydrogen bonding group, and at least one selected from the group consisting of a urethane group, a thiourethane group, a urea group, a thiourea group, an amide group, and a thioamide group is preferable, at least one selected from the group consisting of a urethane group, a urea group, and an amide group is more preferable, and a urea group is still more preferable.

In General Formula (2), Q represents a hydrogen atom or a methyl group, and preferably represents a hydrogen atom.

In General Formula (2), k represents an integer of 2 to 8, and preferably represents an integer of 4 to 8.

Specific examples of the polymerizable compound (a1) are shown below, but the present invention is not limited thereto.

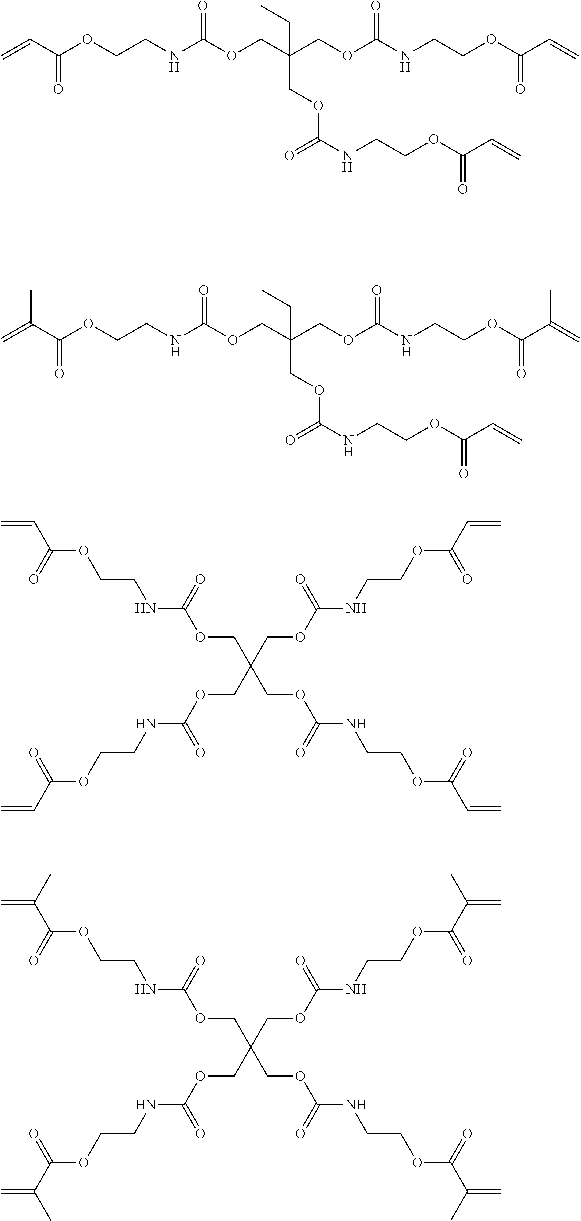

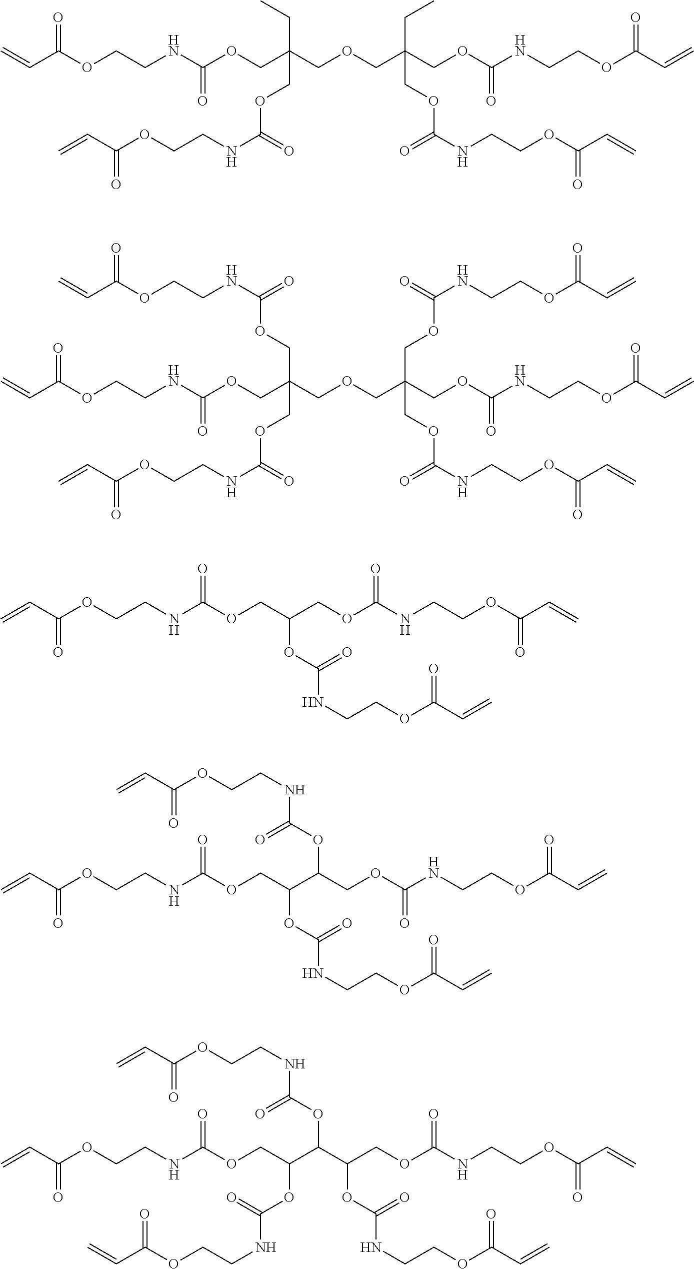

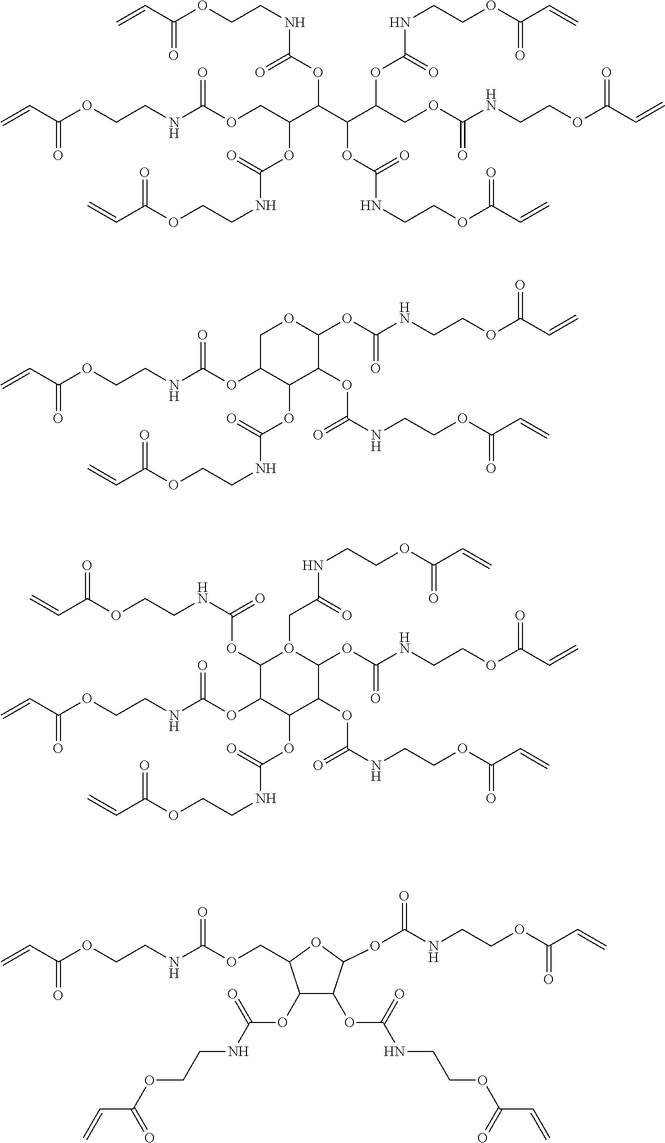

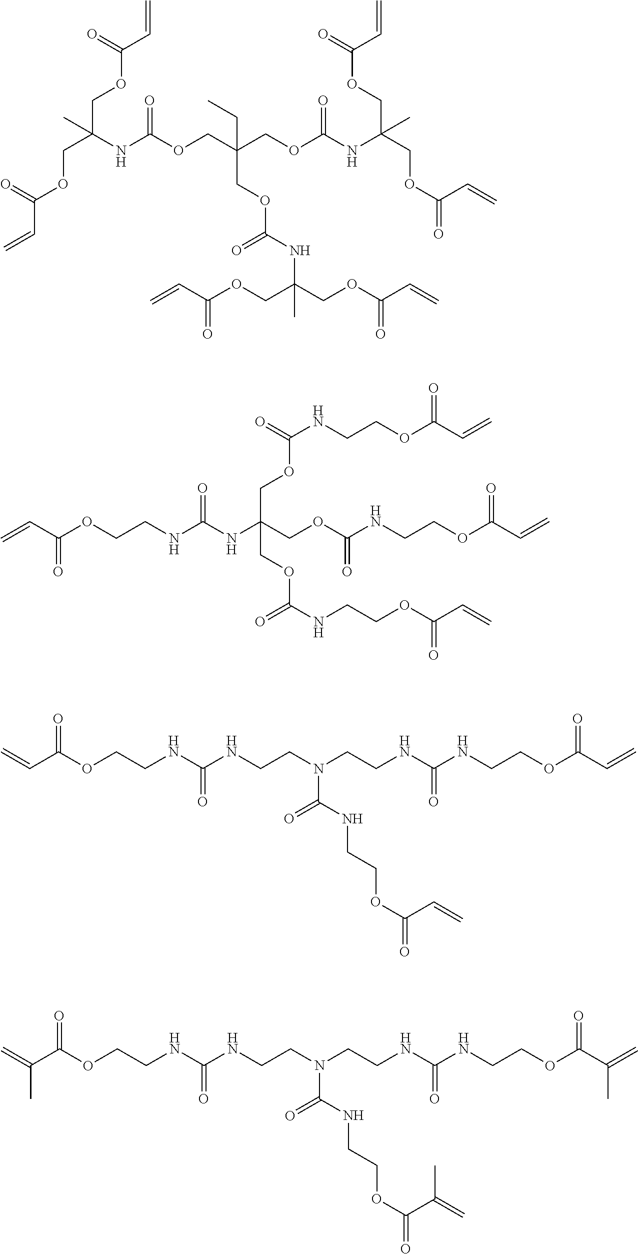

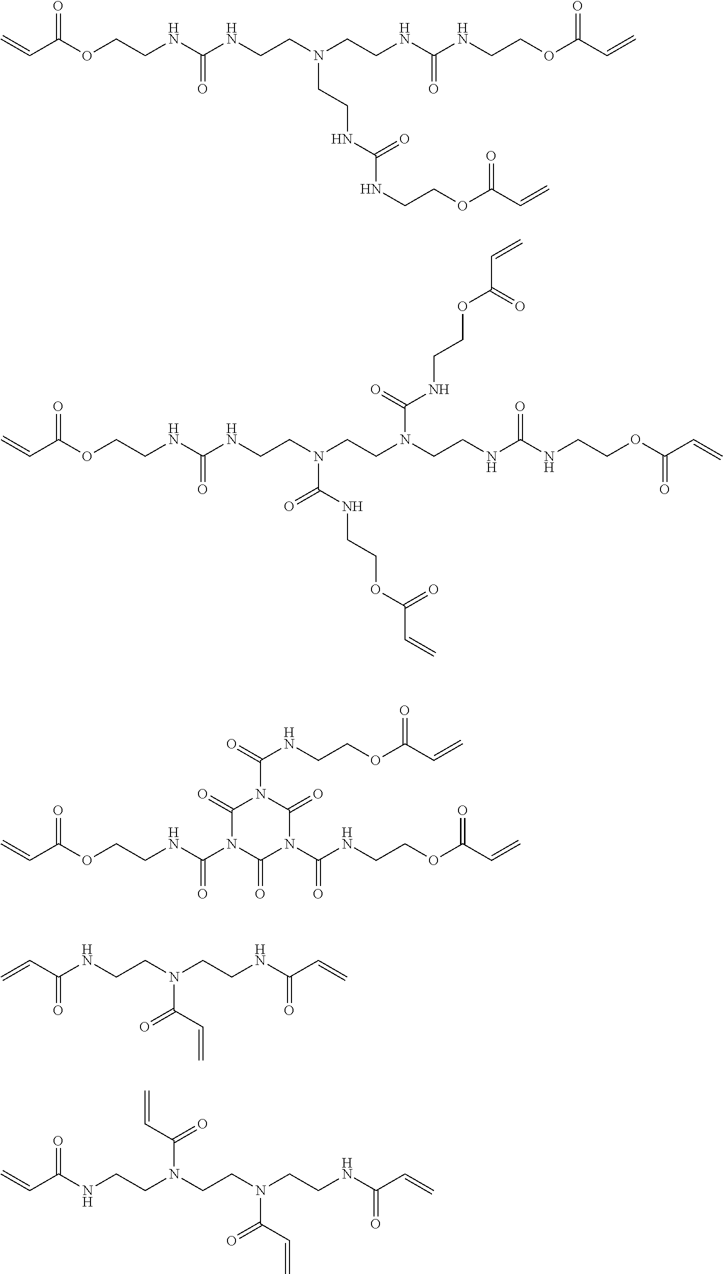

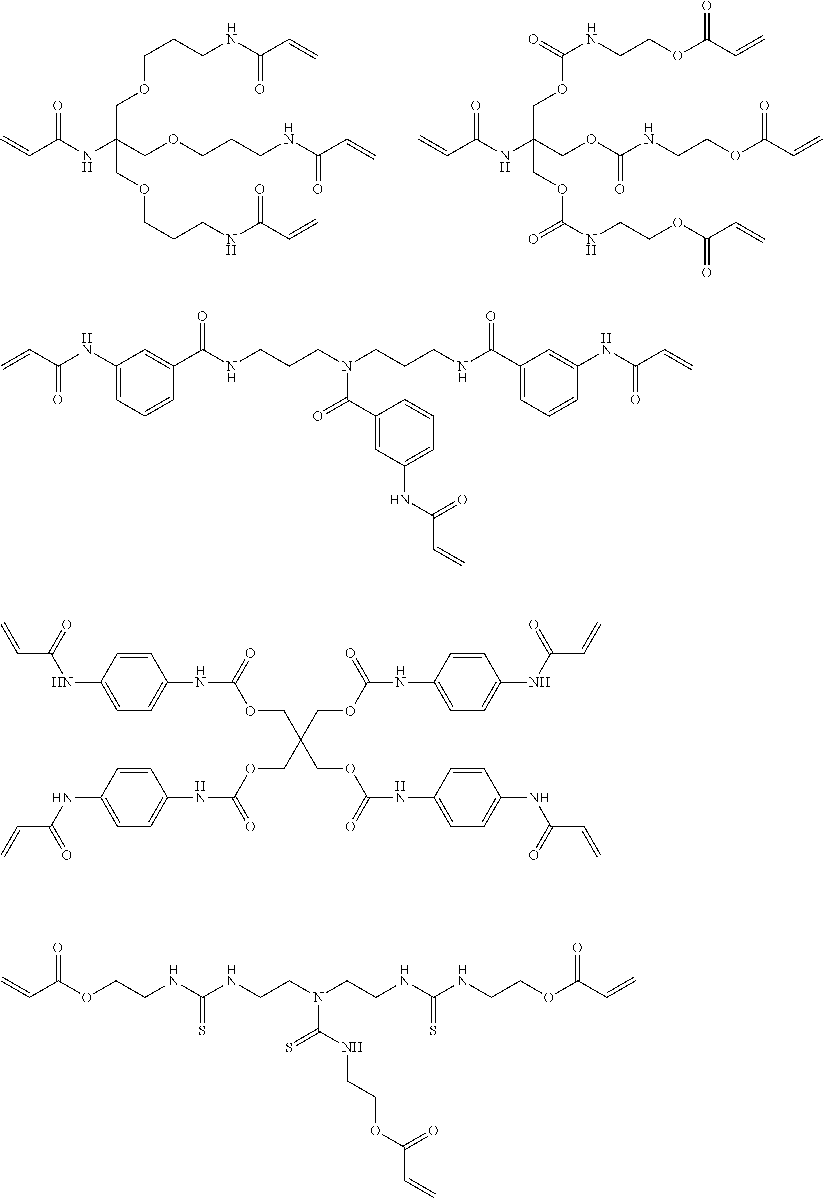

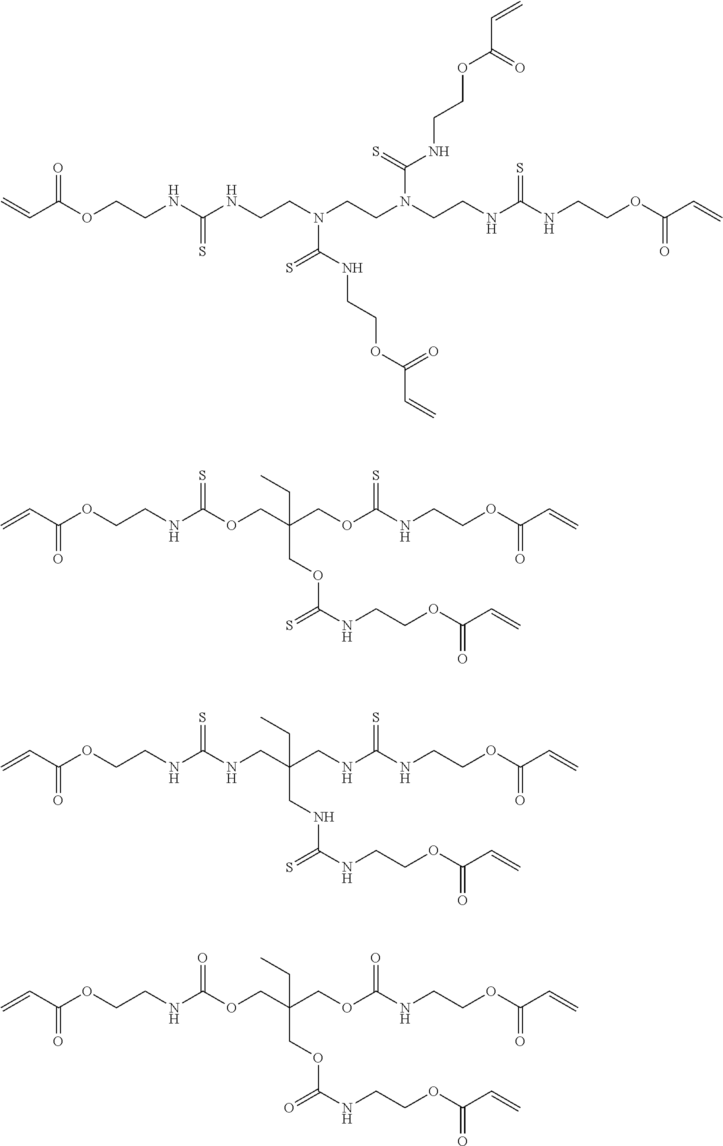

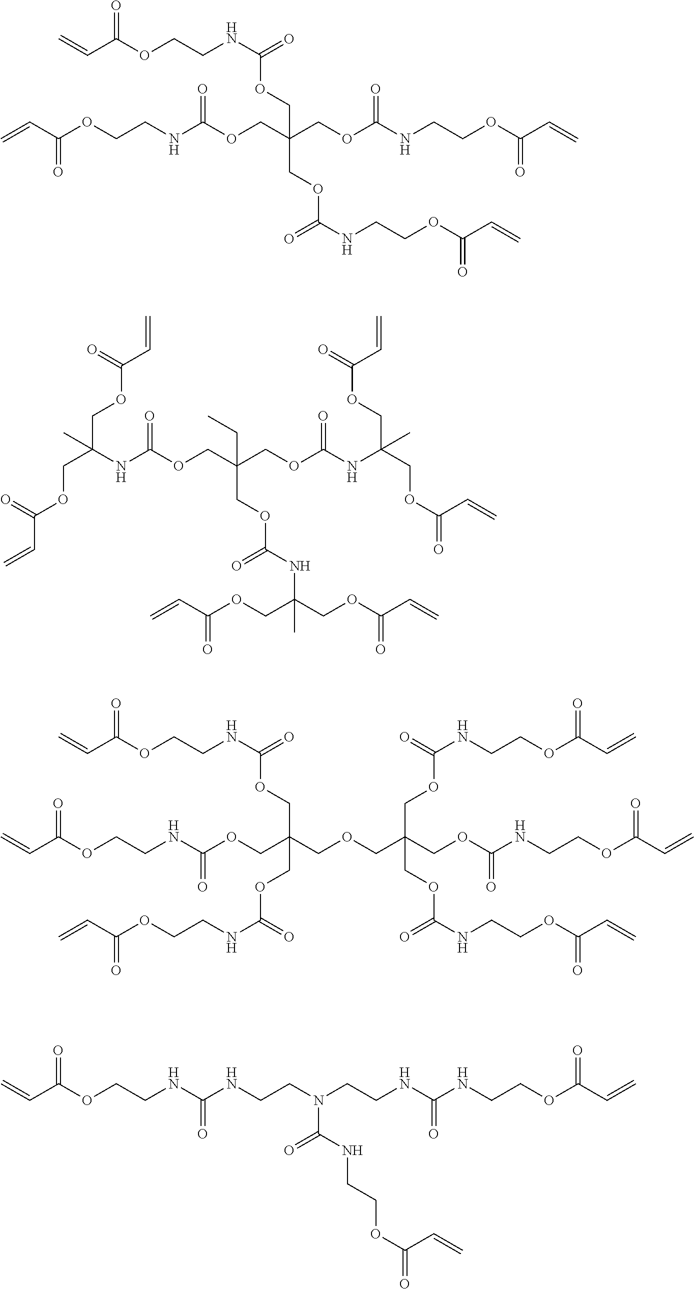

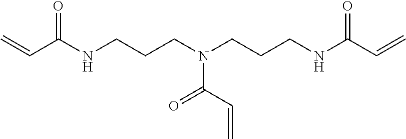 [SMILES: C=CC(=O)NCCCN(CCCNC(=O)C=C)C(=O)C=C]

As another aspect different from the above-described aspect, it is also preferable that the polymerizable compound (a1) is a polyorganosilsesquioxane.

Hereinafter, the polymerizable compound (a1) in the case of polyorganosilsesquioxane will be referred to as a polyorganosilsesquioxane (a1).

The polyorganosilsesquioxane (a1) preferably has a constitutional unit (S1) derived from a hydrolysable silane compound having a (meth)acryloyl group and a constitutional unit (S2) derived from a hydrolysable silane compound having a hydrogen bonding group.

—Constitutional Unit (S1) Derived from Hydrolysable Silane Compound Having (Meth)Acryloyl Group—

The constitutional unit (S1) has a (meth)acryloyl group.

The polyorganosilsesquioxane (a1) may have only one constitutional unit (S1), or two or more constitutional units (S1).

The constitutional unit (S1) is preferably a constitutional unit represented by General Formula (S1-1).

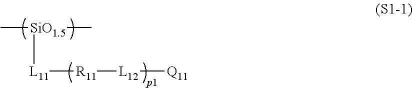

In General Formula (S1-1),
L₁₁ represents a single bond or a divalent linking group,
R₁₁ represents a single bond, —NR—, —O—, —C(═O)—, —S—, —SO—, —SO₂—, or a divalent linking group obtained by combining these groups, where R represents a hydrogen atom or a substituted or unsubstituted alkyl group,
L₁₂ represents a single bond or a substituted or unsubstituted alkylene group,
p1 represents an integer of 0 or more, and
Q₁₁ represents a (meth)acryloyl group.

“SiO_{1.5}” in General Formula (S1-1) represents a structural portion composed of a siloxane bond (Si—O—Si) in the polyorganosilsesquioxane.

The polyorganosilsesquioxane is a network-type polymer or polyhedral cluster having a siloxane constitutional unit (silsesquioxane unit) derived from a hydrolysable trifunctional silane compound, and can form a random structure, a ladder structure, a cage structure, and the like by a siloxane bond. In the present invention, although the structural portion represented by “SiO_{1.5}” may be any of the above-described structures, it is preferable that the structural portion includes a large amount of ladder structures. In a case where the ladder structure is formed, good deformation recovery of a hardcoat film can be maintained. Whether the ladder structure is formed can be qualitatively determined by checking whether or not absorption derived from Si—O—Si stretching unique to the ladder structure, which is found at around 1,020 to 1,050 cm⁻¹ by Fourier Transform Infrared Spectroscopy (FT-IR).

In General Formula (S1-1), in a case where L¹¹ represents a divalent linking group, as the divalent linking group, a divalent linking group consisting of at least one selected from an alkylene group, a cycloalkylene group, an arylene group, —O—, —CO—, —S—, —SO—, —SO₂—, —NR— (R represents a hydrogen atom or a substituted or unsubstituted alkyl group) is preferable; and a divalent linking group consisting of at least one selected from an alkylene group, a cycloalkylene group, an arylene group, or —O— is more preferable. As the above-described alkylene group, an alkylene group having 1 to 10 carbon atoms is preferable, and examples thereof include a methylene group, a methyl methylene group, a dimethyl methylene group, an ethylene group, an i-propylene group, an n-propylene group, an n-butylene group, an n-pentylene group, an n-hexylene group, and an n-decylene group. As the above-described arylene group, an arylene group having 6 to 10 carbon atoms is preferable, and examples thereof include a phenylene group.

In a case where L₁₁ represents a divalent linking group, the divalent linking group may have a substituent, examples of the substituent include a hydroxy group, a carboxy group, an alkoxy group, an aryl group, a heteroaryl group, a halogen atom, a nitro group, a cyano group, and a silyl group.

L₁₁ is preferably an unsubstituted linear alkylene group having 2 to 4 carbon atoms, more preferably an ethylene group or an n-propylene group, and still more preferably an n-propylene group.

In General Formula (S1-1), R₁₁ represents a single bond, —NR—, —O—, —C(═O)—, —S—, —SO—, —SO₂—, or a divalent linking group obtained by combining these groups. R represents a hydrogen atom, or a substituted or unsubstituted alkyl group.

Examples of the divalent linking group obtained by combining —NR—, —O—, and —C(═O)— include *—NH—C(═O)—**, *—C(═O)—NH—**, *—NH—C(═O)—O—**, *—O—C(═O)—NH—**, —NH—C(═O)—NH—, *—C(═O)—O—**, and *—O—C(═O)—**. * represents a bonding site with L₁₁ in General Formula (S1-1), and ** represents a bonding site with L₁₂ in General Formula (S1-1).

R₁₁ is preferably —NH—C(═O)—NH—, *—NH—C(═O)—O—**, *—NH—C(═O)—**, or —O—, and more preferably —NH—C(═O)—NH—, *—NH—C(═O)—O—**, or *—NH—C(═O)—**.

In General Formula (S1-1), L₁₂ represents a single bond or an alkylene group. As the alkylene group, an alkylene group having 1 to 10 carbon atoms is preferable, and examples thereof include a methylene group, a methyl methylene group, a dimethyl methylene group, an ethylene group, an i-propylene group, an n-propylene group, an n-butylene group, an n-pentylene group, an n-hexylene group, and an n-decylene group.

A substituent in a case where the alkylene group represented by L₁₂ has a substituent is not particularly limited, and examples thereof include a hydroxy group, a carboxy group, an alkoxy group, an aryl group, a heteroaryl group, a halogen atom, a nitro group, a cyano group, and a silyl group.

L₁₂ is preferably a linear alkylene group having 1 to 3 carbon atoms, more preferably a methylene group, an ethylene group, an n-propylene group, or a 2-hydroxy-n-propylene group, and still more preferably a methylene group or an ethylene group.

p1 represents an integer of 0 or more, and in a case where p1 represents 2 or more, a plurality of R₁₁'s may be the same or different from each other, and a plurality of Liz's may be the same or different from each other.

p1 preferably represents 0, 1, or 2, and more preferably represents 1 or 2.

In a case where p1 represents 2, it is preferable that L₁₂ in L₁₂-R₁₁ directly bonded to Q₁₁ represents a single bond and R₁₁ represents —O— or —NH—.

—Constitutional Unit (S2) Derived from Hydrolysable Silane Compound Having Hydrogen Bonding Group—

The constitutional unit (S2) has a hydrogen bonding group. The hydrogen bonding group is as described above.

The polyorganosilsesquioxane (a1) may have only one constitutional unit (S2), or two or more constitutional units (S2).

The constitutional unit (S2) is preferably a constitutional unit represented by General Formula (S2-1).

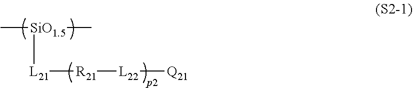

In General Formula (S2-1),
L₂₁ represents a single bond or a divalent linking group,
R₂₁ represents a single bond, —NR—, —O—, —C(═O)—, —S—, —SO—, —SO₂—, or a divalent linking group obtained by combining these groups,
R represents a hydrogen atom or an alkyl group,
L₂₂ represents a single bond or a substituted or unsubstituted alkylene group,
p2 represents an integer of 0 or more, and
Q₂₁ represents a group including a hydrogen bonding group.

“SiO_{1.5}” in General Formula (S2-1) represents a structural portion composed of a siloxane bond (Si—O—Si).

In General Formula (S2-1), in a case where Lei represents a divalent linking group, as the divalent linking group, a divalent linking group consisting of at least one selected from an alkylene group, a cycloalkylene group, an arylene group, —O—, —CO—, —S—, —SO—, —SO₂—, —NR— (R represents a hydrogen atom or a substituted or unsubstituted alkyl group) is preferable; and a divalent linking group consisting of at least one selected from an alkylene group, a cycloalkylene group, an arylene group, or —O— is more preferable.

In a case where L₂₁ represents a divalent linking group, the divalent linking group may have a substituent, examples of the substituent include a hydroxy group, a carboxy group, an alkoxy group, an aryl group, a heteroaryl group, a halogen atom, a nitro group, a cyano group, and a silyl group.

L₂₁ preferably represents an alkylene group and more preferably represents an alkylene group having 1 to 10 carbon atoms, and examples thereof include a methylene group, a methyl methylene group, a dimethyl methylene group, an ethylene group, an i-propylene group, an n-propylene group, an n-butylene group, an n-pentylene group, an n-hexylene group, and an n-decylene group.

Examples of a substituent in a case where the alkylene group represented by L₂₁ has a substituent include a hydroxy group, a carboxy group, an alkoxy group, an aryl group, a heteroaryl group, a halogen atom, a nitro group, a cyano group, and a silyl group.

L₂₁ is preferably an unsubstituted linear alkylene group having 2 to 4 carbon atoms, more preferably an ethylene group or an n-propylene group, and still more preferably an n-propylene group.

In General Formula (S2-1), R₂₁ represents a single bond, —NR—, —O—, —C(═O)—, —S—, —SO—, —SO₂—, or a divalent linking group obtained by combining these groups. R represents a hydrogen atom or an alkyl group.

Examples of the divalent linking group obtained by combining —NR—, —O—, and —C(═O)— include *—NH—C(═O)—**, *—C(═O)—NH—**, *—NH—C(═O)—O—**, *—O—C(═O)—NH—**, —NH—C(═O)—NH—, *—C(═O)—O—**, and *—O—C(═O)—**. * represents a bonding site with L²¹ in General Formula (S2-1), and ** represents a bonding site with L²² in General Formula (S2-1).

R₂₁ is preferably —NH—C(═O)—NH—, *—NH—C(═O)—O—**, *—NH—C(═O)—**, or —O—, and more preferably —NH—C(═O)—NH—, *—NH—C(═O)—O—**, or *—NH—C(═O)—**.

In General Formula (S2-1), L₂₂ represents a single bond or an alkylene group, and as the alkylene group, an alkylene group having 1 to 10 carbon atoms is preferable. Examples thereof include a methylene group, a methyl methylene group, a dimethyl methylene group, an ethylene group, an i-propylene group, an n-propylene group, an n-butylene group, an n-pentylene group, an n-hexylene group, and an n-decylene group.

Examples of a substituent in a case where the alkylene group represented by L₂₂ has a substituent include a hydroxy group, a carboxy group, an alkoxy group, an aryl group, a heteroaryl group, a halogen atom, a nitro group, a cyano group, and a silyl group.

L₂₂ is preferably a linear alkylene group having 1 to 3 carbon atoms, more preferably a methylene group, an ethylene group, an n-propylene group, or a 2-hydroxy-n-propylene group, and still more preferably a methylene group or an ethylene group.

In General Formula (S2-1), Q₂₁ represents a group including a hydrogen bonding group. The hydrogen bonding group is as described above. Q₂₁ may be the hydrogen bonding group.

p2 represents an integer of 0 or more, and in a case where p2 represents 2 or more, a plurality of R₂₁'s may be the same or different from each other, and a plurality of L²²'s may be the same or different from each other.

p2 preferably represents 0, 1, or 2, and more preferably represents 0 or 1.

In a case where the polyorganosilsesquioxane (a1) has the constitutional units (S1) and (S2), a content molar ratio of the constitutional unit (S1) is preferably 10% to 90% by mole, more preferably 20% to 80% by mole, still more preferably 30% to 70% by mole, and particularly preferably 40% to 60% by mole with respect to all constitutional units.

In a case where the polyorganosilsesquioxane (a1) has the constitutional units (S1) and (S2), a content molar ratio of the constitutional unit (S2) is preferably 10% to 90% by mole, more preferably 20% to 80% by mole, still more preferably 30% to 70% by mole, and particularly preferably 40% to 60% by mole with respect to all constitutional units.

As long as it does not affect the effect of the present invention, the polyorganosilsesquioxane (a1) may have a constitutional unit (S3) in addition to the constitutional units (S1) and (S2). In the polyorganosilsesquioxane (a1), a content molar ratio of the constitutional unit (S3) is preferably 10% by mole or less, more preferably 5% by mole or less, and still more preferably 0% by mole with respect to all constitutional units.

A weight-average molecular weight (Mw) of the polyorganosilsesquioxane (a1) is preferably 500 to 500,000, more preferably 10,000 to 100,000, and still more preferably 15,000 to 60,000.

A molecular weight dispersion (Mw/Mn) of the polyorganosilsesquioxane (a1) is not particularly limited, and for example, it is 1.00 to 4.00, preferably 1.10 to 3.70. Mw represents the weight-average molecular weight, and Mn represents the number-average molecular weight.

Unless otherwise specified, the weight-average molecular weight and molecular weight dispersion of the polyorganosilsesquioxane (a1) are values measured by GPC (expressed in terms of polystyrene). Specifically, HLC-8220 (manufactured by TOSOH CORPORATION) is prepared as a device, and the weight-average molecular weight is measured using a differential refractive index (RI) detector under the conditions of a temperature was 23° C. and a flow rate of 1 mL/min by using tetrahydrofuran as an eluent and TSKgel (registered trademark) G3000HXL+TSKgel (registered trademark) G2000HXL as columns.

The polymerized substance of the polymerizable compound (a1) may be one kind of polymerized substance of the polymerizable compound (a1), or may be two or more kinds of polymerized substances (co-polymerized substance) of the polymerizable compounds (a1).

In addition, (A) may be a co-polymerized substance of the polymerizable compound (a1) and another polymerizable compound.

In addition, the polymerizable compound (a1) can be polymerized by a known method, and a known component (for example, a polymerization initiator and the like) can be used in the polymerization.

A content of the polymerized substance derived from the polymerizable compound (a1) in the polymerized substance of (A) is preferably 20% to 100% by mass, more preferably 40% to 100% by mass, and still more preferably 60% to 100% by mass with respect to the total mass of the polymerized substance.

In a case where the protective layer according to the embodiment of the present invention contains (A), a content of (A) is preferably 20% to 100% by mass, more preferably 40% to 100% by mass, and still more preferably 60% to 100% by mass with respect to the total mass of the protective layer.

[(B)]

(B) is a compound including a metal coordinate bond.

Examples of the compound including a metal coordinate bond include a compound including a metal and a ligand, which can form a metal complex.

(B) is preferably a resin including a metal coordinate bond.

In a case where the protective layer contains (B), it is presumed that a metal complex can be formed by the metal coordinate bond to increase the hardness (pencil hardness) of the surface of the protective layer. In addition, since the metal coordinate bond can be reversibly deviated and reformed, it is presumed that stress during strain can be released by the deviation of the metal coordinate bond, and the reformation of the metal coordinate bond after structural change can impart bend resistance to the protective layer. In addition, since the reversible deviation and reformation can occur in a case where an impact force is applied, it is presumed that the protective layer absorbs the force in a thickness direction, and disperses the force in a plane direction, so that anti-scattering properties can be imparted.

For example, (B) is preferably a compound represented by Formula (B-1) or (B-2).

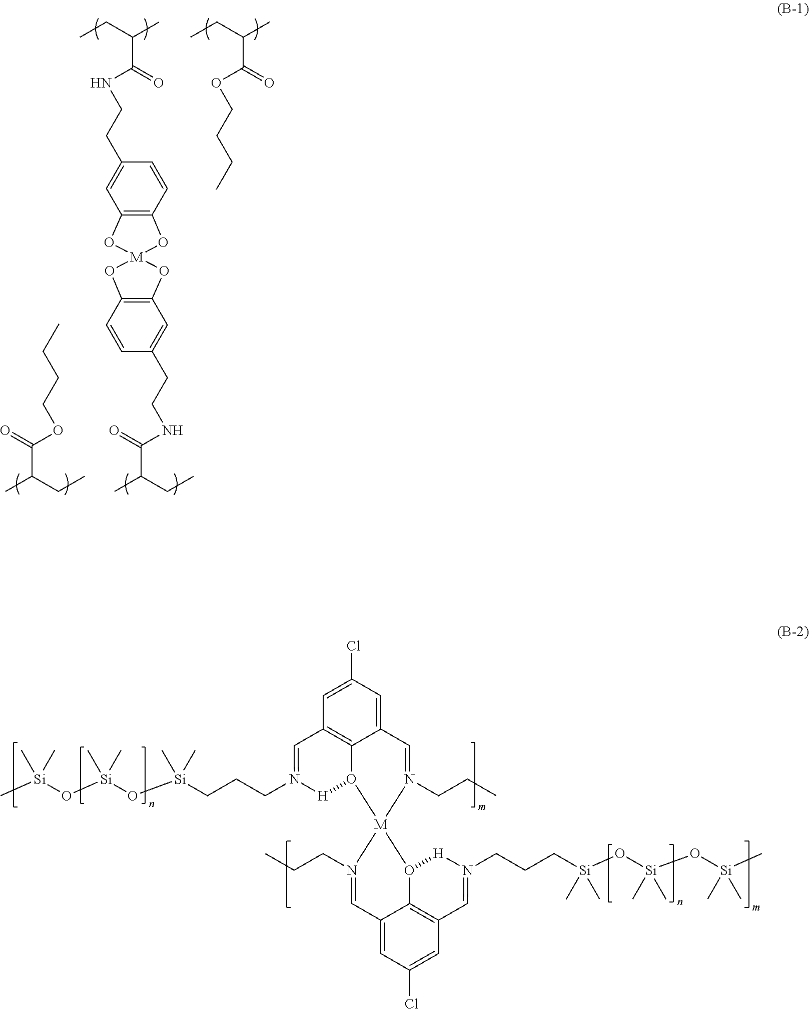

M in Formula (B-1) represents a metal atom, and is preferably calcium or magnesium.

M in Formula (B-2) represents a metal atom, and is preferably zinc. n's each independently represent an arbitrary integer of 0 or more, and m's each independently represent an arbitrary integer of 1 or more.

In a case where the protective layer according to the embodiment of the present invention contains (B), a content of (B) is preferably 10% to 100% by mass, more preferably 20% to 100% by mass, still more preferably 30% to 90% by mass, and particularly preferably 30% to 80% by mass with respect to the total mass of the protective layer. [(C)]

(C) is a compound including a host-guest binding.

Examples of the compound including a host-guest binding include a compound having a structure in which a host molecule encapsulates a guest molecule.

In a case where the protective layer contains (C), it is presumed that the hardness (pencil hardness) of the surface of the protective layer can be increased. In addition, since the host-guest binding can be reversibly deviated and reformed, it is presumed that stress during strain can be released by the deviation of the host-guest binding, and the reformation of the host-guest binding after structural change can impart bend resistance to the protective layer. In addition, since the reversible deviation and reformation can occur in a case where an impact force is applied, it is presumed that the protective layer absorbs the force in a thickness direction, and disperses the force in a plane direction, so that anti-scattering properties can be imparted.

As the host molecule, a compound having cyclodextrin is preferable.

Examples of the host molecule include a polymer obtained by polymerizing at least one compound represented by any of Formulae (H-1) to (H-3).

In Formulae (H-1) to (H-3), R represents a hydrogen atom, an alkyl group, or an acyl group, and preferably represents a methyl group or an acetyl group. A plurality of R's may be the same or different from each other.

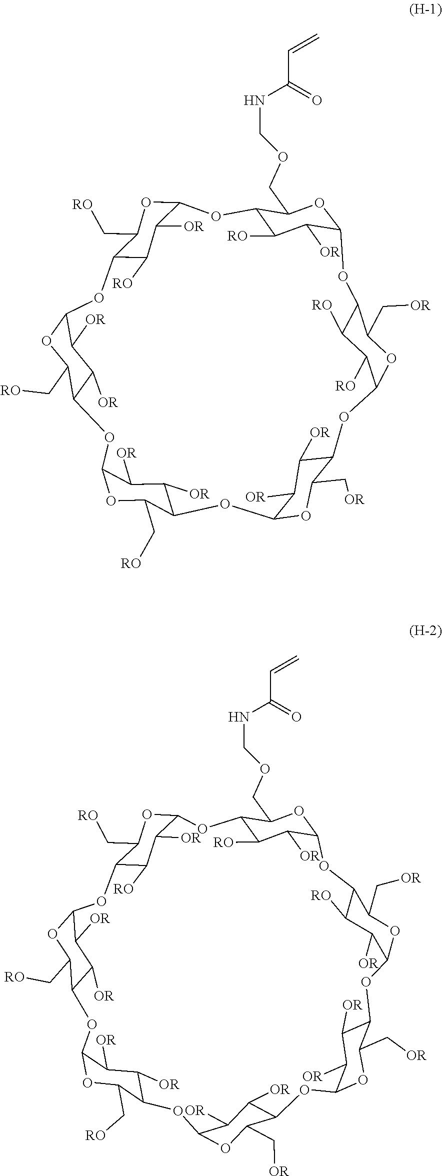

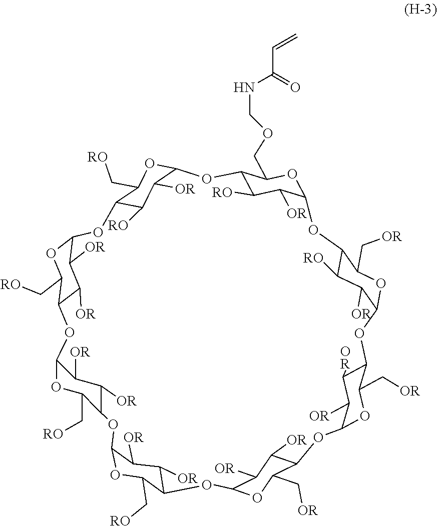

Examples of the guest molecule include a polymer obtained by polymerizing at least one compound represented by any of Formulae (G-1) to (G-3).

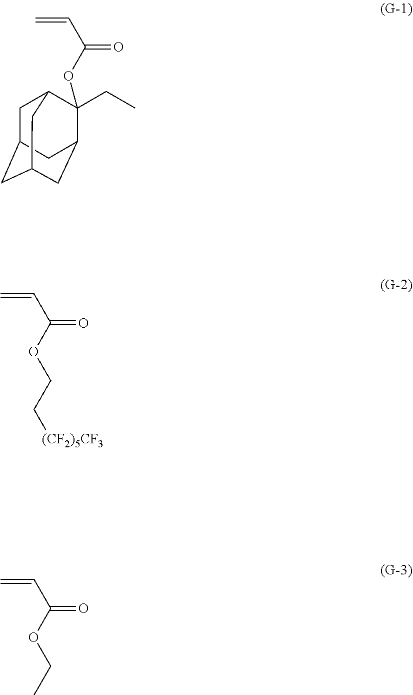

(C) may be a mixture of the host molecule and the guest molecule or may be a copolymer of the host molecule and the guest molecule, and is preferably a copolymer of the host molecule and the guest molecule.

(C) is preferably a compound consisting of the polymer obtained by polymerizing at least one compound represented by any of Formulae (H-1) to (H-3) and the polymer obtained by polymerizing at least one compound represented by any of Formulae (G-1) to (G-3), and more preferably a compound consisting of the polymer obtained by polymerizing Formula (H-1) and the polymer obtained by polymerizing Formula (G-1).

(C) is preferably a polymer obtained by copolymerizing at least one compound represented by any of Formulae (H-1) to (H-3) and at least one compound represented by any of Formulae (G-1) to (G-3); more preferably a polymer obtained by copolymerizing at least one compound represented by any of Formulae (H-1) to (H-3) and at least one compound represented by any of Formula (G-1) or (G-2); and still more preferably a polymer obtained by copolymerizing the compound represented by Formula (H-1) and the compound represented by Formula (G-1).

In a case where the protective layer according to the embodiment of the present invention contains (C), a content of (C) is preferably 10% to 100% by mass, more preferably 20% to 100% by mass, still more preferably 30% to 90% by mass, and particularly preferably 30% to 80% by mass with respect to the total mass of the protective layer.

[Other Components]

The protective layer according to the embodiment of the present invention may contain a component other than the above-described components, and for example, may contain inorganic fine particles, a dispersant, a leveling agent, a lubricant, an antifouling agent, an antistatic agent, an ultraviolet absorber, an antioxidant, or the like.

In the protective layer according to the embodiment of the present invention, it is preferable that an elastic modulus measured under the following measurement conditions is 6 GPa or more and a breaking elongation measured under the following measurement conditions is 10% or more.

Hereinafter, the measurement conditions will be described.

A polyimide film is used as a base material, and the protective layer is coated on the base material to produce a film A. A sample (test piece) having a width of 10 mm and a length of 120 mm is cut out from each of the film A and the base material, and allowed to stand at a temperature of 25° C. and a relative humidity of 60% for 1 hour or longer. Thereafter, using TENSILON RTF-1210 (A&D Company), the sample was pulled under conditions of a pulling speed of 5 mm/sec and a distance between chucks (initial distance between gauge lines) of 100 mm, and a relationship between each elongation and load is measured.

From the difference between the load during each stretching of the film A and the load during stretching of only the base material, a load applied only to the protective layer is calculated, and the elastic modulus is obtained. An elongation rate at the time of breaking is defined as the breaking elongation of the film A.

In addition, cycloolefin is used as a base material, and the protective layer is coated on the base material in the same manner as described above to produce a film B. Only the protective layer is peeled off from the film B, and the breaking elongation is determined under the above-described conditions. Among the breaking elongation of the film A and the breaking elongation of the film B, the larger one is defined as the breaking elongation of the protective layer.

The elastic modulus of the protective layer is preferably 8 GPa or more, more preferably 10 GPa or more, and still more preferably 12 GPa or more.

The breaking elongation of the protective layer is preferably 10% or more, more preferably 15% or more, and still more preferably 23% or more.

A thickness of the protective layer according to the embodiment of the present invention is preferably 10 μm or less, more preferably 1 μm or more and 8 μm or less, and still more preferably 2 μm or more and 7.5 μm or less.

A surface roughness Ra of the surface of the protective layer is preferably 20 nm or less, more preferably 10 nm or less, still more preferably 5 nm or less, and particularly preferably 2 nm or less. In a case where the surface roughness Ra of the surface of the protective layer is small, even a resin is visually recognized as glass, and a high-grade feeling is generated.

The protective layer according to the embodiment of the present invention is a protective layer to be used in a foldable device having a cover window made of glass, and can be preferably used in a foldable device in which a thickness of the cover window made of glass is 100 μm or less. The thickness of the cover window made of glass in the foldable device to which the protective layer according to the embodiment of the present invention is applied is preferably 100 μm or less, more preferably 5 μm or more and 80 μm or less, and still more preferably 10 μm or more and 50 μm or less.

The total light transmittance of the protective layer according to the embodiment of the present invention in a visible range is preferably 85% or more, more preferably 87.5% or more, still more preferably 90.0% or more, and particularly preferably 92.5% or more. [Pressure-sensitive adhesive layer or adhesive layer]

The protective layer according to the embodiment of the present invention can also have a pressure-sensitive adhesive layer or an adhesive layer on at least one surface (that is, the protective layer according to the embodiment of the present invention can be a laminate of the protective layer, and a pressure-sensitive adhesive layer or an adhesive layer (a protective layer with a pressure-sensitive adhesive layer or a protective layer with an adhesive layer)).

A thickness of the pressure-sensitive adhesive layer or the adhesive layer is preferably 1 μm or less, more preferably 0.05 μm or more and 0.9 μm or less, and still more preferably 0.1 μm or more and 0.8 μm or less.

In a case where the protective layer according to the embodiment of the present invention has a pressure-sensitive adhesive layer or an adhesive layer, it is preferable that the pressure-sensitive adhesive layer or the adhesive layer is provided on only one surface of the protective layer, and it is preferable that the pressure-sensitive adhesive layer or the adhesive layer is provided on a surface of a side the cover window made of glass in the foldable device.

The pressure-sensitive adhesive layer and the adhesive layer are not particularly limited, and known pressure-sensitive adhesive layers and adhesive layers can be used.

[Scratch Resistant Layer]

The protective layer according to the embodiment of the present invention can also have a scratch resistant layer on at least one surface (that is, the protective layer according to the embodiment of the present invention can be a laminate of the protective layer and a scratch resistant layer (a protective layer with a scratch resistant layer)).

A thickness of the scratch resistant layer is preferably less than 3.0 μm, more preferably 0.1 to 2.0 and still more preferably 0.1 to 1.0

In a case where the protective layer according to the embodiment of the present invention has a scratch resistant layer, it is preferable that the scratch resistant layer is provided on only one surface of the protective layer, and it is preferable that the scratch resistant layer is provided on a surface of a side the cover window made of glass in the foldable device.

It is preferable that the scratch resistant layer contains at least one of (A) to (C) which can be contained in the protective layer described above. (A) to (C) are as described above.

In a case where the scratch resistant layer contains at least one of (A) to (C), the total content of (A) to (C) is preferably 20% to 100% by mass, more preferably 30% to 100% by mass, and still more preferably 40% to 100% by mass with respect to the total mass of the scratch resistant layer.

In addition, the scratch resistant layer can also contain a cured substance of a composition for forming the scratch resistant layer, which contains a radically polymerizable compound (el).

(Radically Polymerizable Compound (c1))

The radically polymerizable compound (c1) (also called “compound (c1)”) will be described.

The compound (c1) is a compound having a radically polymerizable group.

As the radically polymerizable group in the compound (c1), a generally known radically polymerizable group can be used without particular limitation. Examples of the radically polymerizable group include polymerizable unsaturated groups, and specific examples thereof include a (meth)acryloyl group, a vinyl group, and an allyl group, and the like. Among these, a (meth)acryloyl group is preferable. Each group mentioned above may have a substituent.

The compound (c1) is preferably a compound having two or more (meth)acryloyl groups in one molecule, and more preferably a compound having three or more (meth)acryloyl groups in one molecule.

A molecular weight of the compound (el) is not particularly limited, and the compound (c1) may be a monomer, an oligomer, or a polymer.

[Foldable Device]

The foldable device according to the embodiment of the present invention is a foldable device including a cover window made of glass and a protective layer provided on the cover window, in which the protective layer is the above-described protective layer according to the embodiment of the present invention.

The foldable device is a device which uses a flexible display in which a display screen can be deformed, and it is possible to fold the device main body (display) using deformability of the display screen.

Examples of the foldable device include an organic electroluminescent device.

The cover window is a member attached to protect the display screen of the foldable device, and is typically a sheet-like glass (glass substrate).

A thickness of the cover window made of glass, included in the foldable device according to the embodiment of the present invention, is preferably 100 μm or less, more preferably 5 μm or more and 80 μm or less, and still more preferably 10 μm or more and 50 μm or less.

The foldable device according to the embodiment of the present invention may also include a pressure-sensitive adhesive layer or an adhesive layer between the protective layer and the cover window.

A thickness of the pressure-sensitive adhesive layer or the adhesive layer is preferably 1 μm or less, more preferably 0.05 μm or more and 0.9 μm or less, and still more preferably 0.1 μm or more and 0.8 μm or less.

The pressure-sensitive adhesive layer and the adhesive layer are not particularly limited, and known pressure-sensitive adhesive layers and adhesive layers can be used.

The foldable device according to the embodiment of the present invention can include a scratch resistant layer on a surface of the protective layer opposite to the cover window side.

A thickness of the scratch resistant layer is preferably less than 3.0 μm, more preferably 0.1 to 2.0 μm, and still more preferably 0.1 to 1.0 μm.

It is preferable that the scratch resistant layer contains at least one of (A) to (C) which can be contained in the protective layer described above. (A) to (C) are as described above.

In a case where the scratch resistant layer contains at least one of (A) to (C), the total content of (A) to (C) is preferably 20% to 100% by mass, more preferably 30% to 100% by mass, and still more preferably 40% to 100% by mass with respect to the total mass of the scratch resistant layer.

In addition, the scratch resistant layer can also contain a cured substance of a composition for forming the scratch resistant layer, which contains a radically polymerizable compound (c1). The radically polymerizable compound (c1) is as described above.

### EXAMPLES

Hereinafter, the present invention will be more specifically described with reference to Examples, but the scope of the present invention is not limited thereto.

Structures of compounds used in Examples and Comparative Examples are shown below. (A-1) and (SQ2) are the polymerizable compound (a1). In the following structural formulae, “SiO_{1.5}” represents a silsesquioxane unit. In a constitutional unit of each polymer, a compositional ratio of each constitutional unit is a molar ratio. Mw represents a weight-average molecular weight.

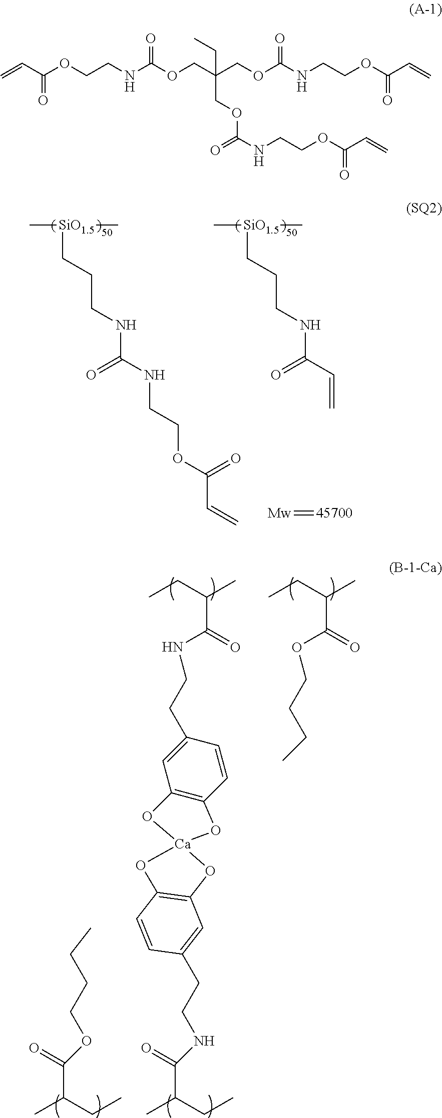

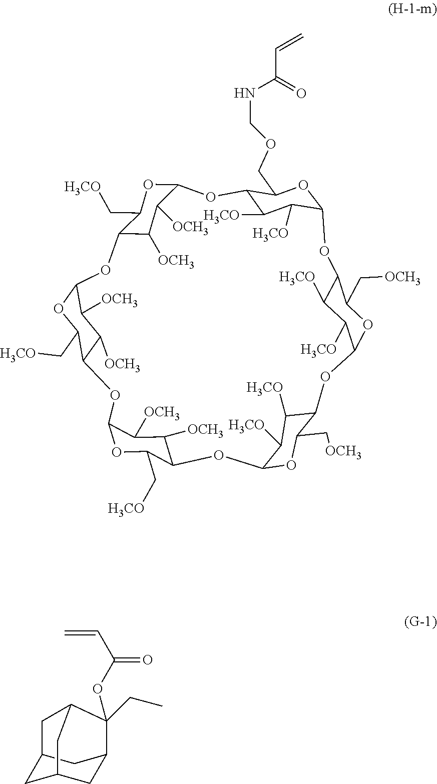 [SMILES: C=CC(=O)NCOCC1OC2OC3C(COC)OC(OC4C(COC)OC(OC5C(COC)OC(OC6C(COC)OC(OC7C(COC)OC(OC1C(OC)C2OC)C(OC)C7OC)C(OC)C6OC)C(OC)C5OC)C(OC)C4OC)C(OC)C3OC ; C=CC(=O)OC1(CC)C2CC3CC(C2)CC1C3]

### Examples 1 to 9, 15, 16, and Comparative Examples 4 and 5

<Preparation of Curable Composition>

(Curable Compositions HC-1 to HC-10)

The content of each component was adjusted as shown in Table 1 below, and the mixture was charged into a mixing tank and stirred. The obtained composition was filtered through a polypropylene filter having a pore diameter of 0.45 nm, thereby preparing curable compositions HC-1 to HC-10. Numerical values in Table 1 indicate the addition amount of each component, and the unit thereof is part by mass.

TABLE 1

| | HC-1 | HC-2 | HC-3 | HC-4 | HC-5 | HC-6 | HC-7 | HC-8 | HC-9 | HC-10 |
|---|---|---|---|---|---|---|---|---|---|---|
| (SQ2) | 84.8 | | | | | | | | | |
| (A-1) | | 64.8 | | | 65.8 | | | | 60 | 60 |
| (B-1-Ca) | | | 24.8 | | | | | | 24.8 | |
| (H-1-m)/(G-1) | | | | 24.8 | | 25.8 | | | | 24.8 |
| elastomer | | | | | | | | | | |
| A-TMMT | | 20 | 60 | 60 | 20 | 60 | | | | |
| DPCA-20 | | | | | | | 84.8 | | | |
| DPCA-120 | | | | | | | | 84.8 | | |
| Aluminum | 0.2 | 0.2 | 0.2 | 0.2 | 0.2 | 0.2 | 0.2 | 0.2 | 0.2 | 0.2 |
| acetylacetonate | | | | | | | | | | |
| IRGACURE 127 | 4 | 4 | 4 | 4 | 4 | 4 | 4 | 4 | 4 | 4 |
| KBM-5103 | 10 | 10 | 10 | 10 | 10 | 10 | 10 | 10 | 10 | 10 |
| RS-90 | 1 | 1 | 1 | 1 | 0 | 0 | 1 | 1 | 1 | 1 |
| Methyl isobutyl | 100 | 100 | 100 | 100 | 100 | 100 | 100 | 100 | 100 | 100 |
| ketone | | | | | | | | | | |

The compounds used are as follows.

IRGACURE 127 (Irg. 127): manufactured by BASF

A-TMMT: pentaerythritol tetraacrylate (manufactured by SHIN-NAKAMURA CHEMICAL CO, LTD.)

DPCA-20: KAYARAD DPCA-20 (manufactured by Nippon Kayaku Co., Ltd.)

DPCA-120: KAYARAD DPCA-120 (manufactured by Nippon Kayaku Co., Ltd.)

KBM-5103 (manufactured by Shin-Etsu Chemical Co., Ltd.)

RS-90: lubricant, manufactured by DIC Corporation (concentration of solid contents: 10% by mass)

[Synthesis of (SQ2)]

300 mmol (53.8 g) of 3-aminopropyltrimethoxysilane and 166 g of methyl isobutyl ketone were mixed with each other, this solution was cooled to 5° C. or lower, 300 mmol (42.3 g) of 2-acryloyloxyethyl isocyanate was added dropwise thereto, and after reaction, the temperature was raised to room temperature. Thereafter, 300 mmol (70.0 g) of 3-(trimethoxysilyl)propyl acrylamide, 7.39 g of triethylamine, and 434 g of acetone were mixed with each other, and 73.9 g of pure water was added dropwise thereto for 30 minutes by using a dropping funnel. The reaction solution was heated to 50° C., and a polycondensation reaction was carried out for 10 hours.

Thereafter, the reaction solution was cooled and neutralized with 12 mL of a 1 mol/L hydrochloric acid aqueous solution, 600 g of 1-methoxy-2-propanol was added thereto, and then the mixture was concentrated under the conditions of 30 mmHg and 50° C., thereby obtaining (SQ2) which is a transparent liquid product as a propylene glycol monomethyl ether (PGME) solution having a concentration of solid contents of 35% by mass. 1 mmHg is 101,325/760 Pa.

(B-1-Ca) was synthesized according to a method described in Appl. Mater. Interfaces 2016, 8, pp. 19047 to 19053. In this case, a molar ratio of dopamine acrylamide and butyl acrylate was 80:20, and calcium was used as the metal M.

(B-1-Ca) is the compound including a metal coordinate bond.

An (H-1-m)/(G-1) elastomer was synthesized according to a method described in Macromolecules 2019, 52, pp. 2659 to 2668 in which a molar ratio of (H-1-m) and (G-1) was 50:50. (H-1-m) is a compound in which R in (H-1) described above is a methyl group.

The (H-1-m)/(G-1) elastomer is the compound including a host-guest binding.

(Manufacturing of Protective Layer)

A glass substrate (manufactured by Nippon Electric Glass Co., Ltd., G-Leaf) having a thickness shown in Tables 2 and 3 below was bar-coated with the curable composition shown in Tables 2 and 3 below using a wire bar such that a film thickness after curing was a thickness shown in Tables 2 and 3 below, thereby providing a protective layer coating film on the glass substrate.

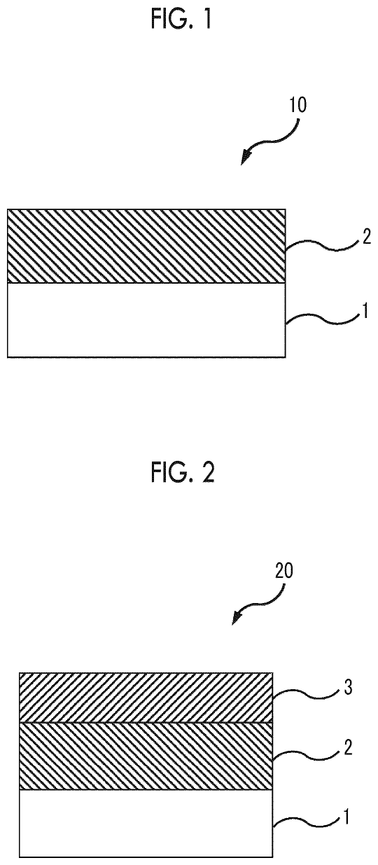

Next, the protective layer coating film was dried at 120° C. for 5 minutes, and then irradiated with ultraviolet rays with an irradiation amount of 300 mJ/cm 2, using an air-cooled mercury lamp under the conditions of 25° C. and an oxygen concentration of 100 parts per million (ppm). The protective layer coating film was cured in this manner to form a protective layer on the glass substrate. In this way, the samples of Examples 1 to 9, 15, and 16, and Comparative Examples 4 and 5 were produced (see FIG. 1).

TABLE 2

| | Exam- | Exam- | Exam- | Exam- | Exam- | Exam- | Exam- | Exam- | Exam- | Exam- | Exam- |
|---|---|---|---|---|---|---|---|---|---|---|---|
| | ple 1 | ple 2 | ple 3 | ple 4 | ple 5 | ple 6 | ple 7 | ple 8 | ple 9 | ple 15 | ple 16 |
| Thickness | 120 | 200 | 50 | 50 | 50 | 50 | 50 | 50 | 50 | 50 | 50 |
| of glass | | | | | | | | | | | |
| substrate | | | | | | | | | | | |
| (μm) | | | | | | | | | | | |
| Curable | HC-1 | HC-1 | HC-1 | HC-2 | HC-3 | HC-4 | HC-2 | HC-2 | HC-2 | HC-9 | HC-10 |
| composition | | | | | | | | | | | |
| Thickness | 5 | 5 | 5 | 5 | 5 | 5 | 1 | 10 | 15 | 5 | 5 |
| of protective | | | | | | | | | | | |
| layer (μm) | | | | | | | | | | | |

TABLE 3

| | Comparative | Comparative |
|---|---|---|
| | Example 4 | Example 5 |
| Thickness of glass | 50 | 50 |
| substrate (μm) | | |
| Curable composition | HC-8 | HC-7 |
| Thickness of protective | 5 | 5 |
| layer (μm) | | |

### Comparative Example 1

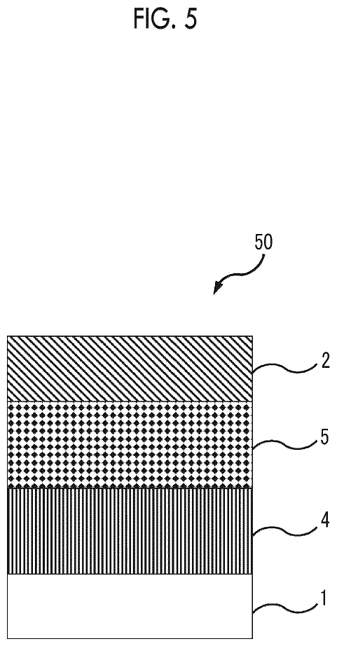

A glass substrate (manufactured by Nippon Electric Glass Co., Ltd., G-Leaf) having a thickness of 50 μm was used as a sample of Comparative Example 1 (without a protective layer) (see FIG. 4).

### Examples 10 to 12

A glass substrate (manufactured by Nippon Electric Glass Co., Ltd., G-Leaf) having a thickness shown in Table 4 below was bar-coated with the curable composition shown in Table 4 below using a wire bar such that a film thickness after curing was a thickness shown in Table 4 below, thereby providing a protective layer coating film on the glass substrate.

Next, the protective layer coating film was dried at 120° C. for 5 minutes, and then irradiated with ultraviolet rays with an irradiation amount of 60 mJ/cm 2, using an air-cooled mercury lamp under the conditions of 25° C. and an oxygen concentration of 100 parts per million (ppm). The protective layer coating film was cured in this manner to form a protective layer on the glass substrate.

TABLE 4

| | Example 10 | Example 11 | Example 12 |
|---|---|---|---|
| Thickness of glass | 50 | 50 | 50 |
| substrate (μm) | | | |
| Curable composition | HC-5 | HC-5 | HC-6 |
| Thickness of protective | 5 | 5 | 5 |
| layer (μm) | | | |

(Composition SR-1 for Forming Scratch Resistant Layer)

Each component was charged into a mixing tank with the composition described below, stirred, and filtered through a polypropylene filter having a pore diameter of 0.4 μm, thereby obtaining a composition SR-1 for forming a scratch resistant layer.

| | |
|---|---|
| A-TMMT | 26.2 parts by mass |
| DPCA-30 | 7.1 parts by mass |
| IRGACURE 127 | 1.0 part by mass |
| Conductive compound A | 3.2 parts by mass |
| RS-90 | 3.5 parts by mass |
| Methyl ethyl ketone | 50.4 parts by mass |

The compounds used in the composition for forming a scratch resistant layer are as follows.

A-TMMT: pentaerythritol tetraacrylate (manufactured by SHIN-NAKAMURA CHEMICAL CO, LTD.)

DPCA-30: KAYARAD DPCA-30 (manufactured by Nippon Kayaku Co., Ltd.)

RS-90: lubricant, manufactured by DIC Corporation (concentration of solid contents: 10% by mass)

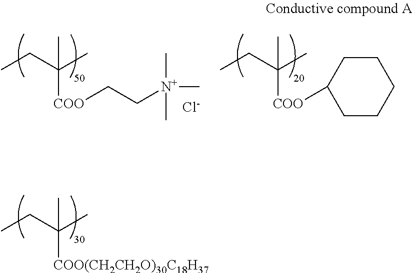

(Method for Synthesizing Conductive Compound A)

58.25 g of ethanol was put into a 500 mL three-neck flask provided with a stirrer, a thermometer, a reflux condenser, and a nitrogen gas introduction pipe, and then heated to 70° C. Next, a mixed solution consisting of 62.14 g (299.18 mmol) of trimethyl-2-methacroyloxyethylammonium chloride (80% aqueous solution), 20.00 g (118.88 mmol) of cyclohexyl methacrylate, 30.00 g (18.07 mmol) of Blemmer PSE1300 (manufactured by NOF Corporation), 167.90 g of ethanol, and 24.50 g of azobisisobutyronitrile was added dropwise thereto at a constant rate so that the dropwise addition was completed in 3 hours. After completion of the dropwise addition, a mixed solution of 0.40 g of azobisisobutyronitrile and 19.10 g of ethanol was added thereto, and the mixture was further stirred for 3 hours, heated to 78.5° C., and then further stirred for 8 hours, thereby obtaining 360.00 g (concentration of a polymer ethanol solution (concentration of solid contents: 28% by mass).

(Composition SR-2 for Forming Scratch Resistant Layer)

Each component was charged into a mixing tank with the composition described below, stirred, and filtered through a polypropylene filter having a pore diameter of 0.4 thereby obtaining a composition SR-2 for forming a scratch resistant layer.

| | |
|---|---|
| A-TMMT | 16.7 parts by mass |
| (A-1) | 16.7 parts by mass |
| IRGACURE 127 | 1.0 part by mass |
| Conductive compound A | 3.2 parts by mass |
| RS-90 | 3.5 part by mass |
| Methyl ethyl ketone | 50.4 part by mass |

(Manufacturing of Protective Layer with Scratch Resistant Layer)

The composition for forming a scratch resistant layer shown in Table 5 was applied to a surface of the protective layer of Examples 10 to 12 opposite to the glass substrate side using a die coater such that a film thickness after curing was 1

Next, the obtained laminate was dried at 120° C. for 1 minute, and then irradiated with ultraviolet rays at an illuminance of 60 mW/cm 2, an irradiation amount of 600 mJ/cm 2, and an oxygen concentration of 100 ppm at 25° C. and further irradiated with ultraviolet rays at an illuminance of 60 mW/cm 2 and an irradiation amount of 600 mJ/cm 2, by using an air-cooled mercury lamp under the conditions of 100° C. and an oxygen concentration of 100 ppm, thereby forming a protective layer with a scratch resistant layer. In this way, the samples of Examples 10 to 12 were produced (see FIG. 2).

TABLE 5

| | Example 10 | Example 11 | Example 12 |
|---|---|---|---|
| Composition for forming | SR-1 | SR-2 | SR-2 |
| scratch resistant layer | | | |

### Example 13

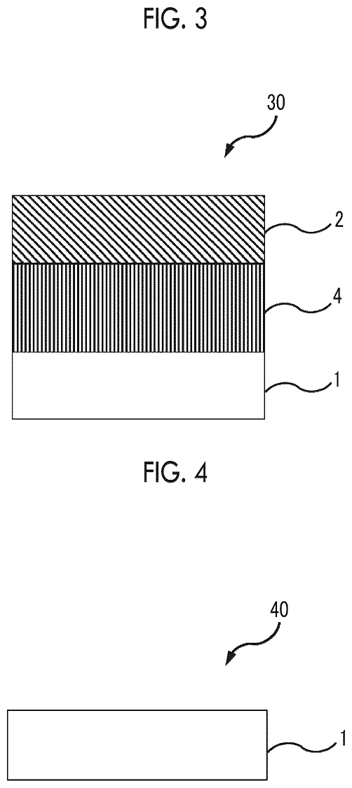

The curable composition HC-5 was applied onto a cycloolefin substrate using a wire bar such that a film thickness after curing was 5 Next, the protective layer coating film was dried at 120° C. for 1 minute, and then irradiated with ultraviolet rays with an irradiation amount of 300 mJ/cm 2, using an air-cooled mercury lamp under the conditions of 25° C. and an oxygen concentration of 100 parts per million (ppm), thereby forming a protective layer. Next, a glass substrate (manufactured by Nippon Electric Glass Co., Ltd., G-Leaf) having a thickness of 50 μm was coated with Aron Alpha (registered trademark) (manufactured by Toagosei Co., Ltd.) such that a thickness was 10 and it was laminated with a roller so as to be in contact with the protective layer formed on the cycloolefin substrate, and left for 24 hours. Thereafter, the cycloolefin substrate was peeled off from the protective layer to produce the sample of Example 13 (see FIG. 3).

### Example 14

The sample was produced in the same manner as in Example 13, except that the thickness of Aron Alpha (registered trademark) (manufactured by Toagosei Co., Ltd.) was 1

### Comparative Example 2

The curable composition HC-7 was applied onto a polyethylene terephthalate (PET) substrate having a thickness of 40 μm using a wire bar such that a film thickness after curing was 5 Next, the protective layer coating film was dried at 120° C. for 1 minute, and then irradiated with ultraviolet rays with an irradiation amount of 300 mJ/cm 2, using an air-cooled mercury lamp under the conditions of 25° C. and an oxygen concentration of 100 parts per million (ppm), thereby forming a protective layer. The obtained PET substrate with the protective layer was laminated to a glass substrate (manufactured by Nippon Electric Glass Co., Ltd., G-Leaf) having a thickness of 50 μm using a pressure-sensitive adhesive having a thickness of 30 μm. In this way, the sample of Comparative Example 2 was produced (see FIG. 5).

### Comparative Example 3

The curable composition HC-7 was applied onto a PET substrate having a thickness of μm using a wire bar such that a film thickness after curing was 5 Next, the protective layer coating film was dried at 120° C. for 1 minute, and then irradiated with ultraviolet rays with an irradiation amount of 300 mJ/cm 2, using an air-cooled mercury lamp under the conditions of and an oxygen concentration of 100 parts per million (ppm), thereby forming a protective layer. A glass substrate having a thickness of 50 μm was coated with Aron Alpha (registered trademark) (manufactured by Toagosei Co., Ltd.) having a thickness of 1 and it was laminated with a roller so as to be in contact with the PET substrate side in the PET substrate with the protective layer, and left for 24 hours, thereby producing the sample of Comparative Example 3 (see FIG. 5).

[Evaluation]

The manufactured sample of each of Examples and Comparative Examples was evaluated by the following methods. The evaluation results are shown in Tables 6 and 7.

(Elastic Modulus and Breaking Elongation)

The elastic modulus and the breaking elongation were measured under the above-described measurement conditions.

(Pencil Hardness)

Pencil hardness was evaluated according to JIS (JIS stands for Japanese Industrial Standards) K5400. The protective layer (laminate including the glass substrate and the protective layer) of each of Examples and Comparative Examples was conditioned at a temperature of 25° C. and a relative humidity of 60% for 2 hours, and then five different points on the surface of the protective layer (in the sample including a scratch resistant layer, surface of the scratch resistant layer, and in the sample not including a protective layer, surface of the glass substrate) were scratched with a load of 750 g using a test pencil of H to 9H specified in JIS S 6006. Thereafter, among hardnesses of pencils in which scratches were observed at 0 to 2 points, the highest pencil hardness was used as the evaluation result. For the pencil hardness, as the numerical value described before “H” is higher, the hardness is higher, which is preferable.

The pencil hardness was evaluated according to the following standard.

A: 5H or more, B: 4H or more and less than 5H, C: 3H or more and less than 4H, D: H or more and less than 3H, E: less than H

(Bend Resistance)

Each sample (laminate including the glass substrate and the protective layer) was evaluated using Testing methods for paints—bend test (cylindrical mandrel) described in JIS-K-5600-5-1. Each sample was stored for 1 hour under the conditions of a temperature 25° C. and a relative humidity 55%, and then wound around mandrels having a diameter (1) of 2, 3, 4, 5, 6, 8, 10, 12, 14, or 16 mm with the coated surface (the protective layer or the scratch resistant layer) facing outward (the glass substrate facing inward). The way the cracks occurred was observed, and the bend resistance was evaluated based on the diameter of the smallest mandrel that did not cause cracks. As the diameter (1) of the mandrel is smaller, the bend resistance is more excellent, and as the diameter at which cracks occur is larger, the bend resistance is deteriorated. The presence of absence of cracks was visually determined.

The bend resistance was evaluated according to the following standard.

A: 4 mmΦ or less, B: more than 4 mmΦ and 8 mmΦ or less, C: more than 8 mmΦ and 12 mmΦ or less, D: more than 12 mmΦ

(Smoothness)

With the surface of the protective layer (in the sample including a scratch resistant layer, surface of the scratch resistant layer, and in the sample not including a protective layer, surface of the glass substrate), using Vertscan 2.0 (manufactured by Ryoka Systems Inc.), the surface roughness Ra was measured at a visual field size of 3724 μm×4965 μm with a lens magnification of 2.5, a barrel magnification of 0.5, and Wave mode.

The surface roughness Ra was preferably 20 nm or less, more preferably 10 nm or less, still more preferably 5 nm or less, and particularly preferably 2 nm or less.

(Anti-Scattering Properties)

The sample of Examples and Comparative Examples, having a size of 5 cm×5 cm, was placed on a smooth table, and a degree of scattering of the sample in a case where a 100 g iron ball was freely dropped from a height of 30 cm was evaluated using the following indicators. Here, the degree of scattering was defined as a ratio (%) of the mass of the peeled portion after the evaluation and the mass of the sample before the evaluation.

Degree of scattering (=100×mass of peeled portion (g)/mass before evaluation (g))

A: less than 20%, B: 20% or more and less than 40%, C: 40% or more and less than 60%, D: 60% or more and less than 80%, E: 80% or more

(Scratch Resistance)

Using a rubbing tester, the surface of the protective layer (in the sample including a scratch resistant layer, surface of the scratch resistant layer, and in the sample not including a protective layer, surface of the glass substrate) in each sample (laminate including the glass substrate and the protective layer) was subjected to a rubbing test under the following conditions to obtain an indicator of scratch resistance.

Environmental conditions for evaluation: 25° C. and relative humidity of 60%
Rubbing Material: steel wool (manufactured by NIHON STEEL WOOL Co., Ltd., grade No. #0000)

The steel wool was wound around the rubbing tip portion (2 cm×2 cm) of the tester coming into contact with the sample and fixed with a band.
Moving distance (one way): 13 cm
Rubbing speed: 13 cm/sec
Load: 1 kg/cm 2
Contact area of tip portion: 1 cm×1 cm
Number of times of rubbing: rubbed back and forth 10 times, 100 times, and 1000 times

After the test, an oil-based black ink was applied to a surface (surface of the glass substrate) opposite to the rubbed surface of the sample. Reflected light was visually observed, the number of times of rubbing that caused scratches in the portion contacting the steel wool was counted, and the scratch resistance was evaluated.
A: no scratch occurred even though the sample was rubbed back and forth 1000 times.
B: no scratch occurred even though the sample was rubbed back and forth 100 times, but in a case where the sample was rubbed back and forth 1000 times, scratches occurred.
C: no scratch occurred even though the sample was rubbed back and forth 10 times, but in a case where the sample was rubbed back and forth 100 times, scratches occurred.
D: scratches occurred in a case where the sample was rubbed back and forth 10 times.

TABLE 6

| | Compar- | Compar- | Compar- | Compar- | Compar- | | | | |
|---|---|---|---|---|---|---|---|---|---|
| | ative | ative | ative | ative | ative | | | | |
| | Exam- | Exam- | Exam- | Exam- | Exam- | Exam- | Exam- | Exam- | Exam- |
| | ple 1 | ple 2 | ple 3 | ple 4 | ple 5 | ple 1 | ple 2 | ple 3 | ple 4 |
| Hydrogen-bonding | — | 0 | 0 | 0 | 0 | 7.2 | 7.2 | 7.2 | 5.4 |
| proton value | | | | | | | | | |
| (mol/kg) | | | | | | | | | |
| (Meth)acryloyl | — | 7.4 | 7.4 | 3.1 | 7.4 | 4.8 | 4.8 | 4.8 | 5.4 |
| value (mol/kg) | | | | | | | | | |
| Elastic modulus | — | 7.8 | 7.8 | 2.3 | 7.8 | 7.2 | 7.2 | 7.2 | 10.1 |
| of protective | | | | | | | | | |
| layer (GPa) | | | | | | | | | |
| Breaking | — | 3% | 3% | 10% | 3% | 10% | 10% | 10% | 23% |
| elongation of | | | | | | | | | |
| protective layer | | | | | | | | | |
| Thickness of | — | 5 | 5 | 5 | 5 | 5 | 5 | 5 | 5 |
| protective layer | | | | | | | | | |
| (μm) | | | | | | | | | |
| Thickness of | — | 30 | 1 | — | — | — | — | — | — |
| pressure-sensitive | | | | | | | | | |
| adhesive layer of | | | | | | | | | |
| adhesive layer (μm) | | | | | | | | | |
| Smoothness (nm) | 1 | 30 | 30 | 5 | 5 | 5 | 5 | 5 | 5 |
| Pencil hardness | A | E | D | E | B | B | B | B | B |
| Anti-scattering | E | A | B | B | D | C | C | C | B |
| properties | | | | | | | | | |
| Scratch resistance | A | B | B | B | B | B | B | B | B |
| Bend resistance | A | A | A | A | A | B | C | A | A |

TABLE 7

| | Exam- | Exam- | Exam- | Exam- | Exam- | Exam- | Exam- | Exam- | Exam- | Exam- | Exam- | Exam- |
|---|---|---|---|---|---|---|---|---|---|---|---|---|
| | ple 5 | ple 6 | ple 7 | ple 8 | ple 9 | ple 10 | ple 11 | ple 12 | ple 13 | ple 14 | ple 15 | ple 16 |
| Hydrogen- | — | — | 5.4 | 5.4 | 5.4 | 5.4 | 5.4 | — | 5.4 | 5.4 | — | — |
| bonding proton | | | | | | | | | | | | |
| value (mol/kg) | | | | | | | | | | | | |
| (Meth)acryloyl | — | — | 5.4 | 5.4 | 5.4 | 5.4 | 5.4 | — | 5.4 | 5.4 | — | — |
| value | | | | | | | | | | | | |
| (mol/kg) | | | | | | | | | | | | |
| Elastic modulus | 7.4 | 6.4 | 10.1 | 10.1 | 10.1 | 10.1 | 10.1 | 6.4 | 10.1 | 10.1 | 7.2 | 6.1 |
| of protective | | | | | | | | | | | | |
| layer (GPa) | | | | | | | | | | | | |
| Breaking | 40% | 100% | 23% | 23% | 23% | 23% | 23% | 100% | 23% | 23% | 52% | 117% |
| elongation of | | | | | | | | | | | | |
| protective layer | | | | | | | | | | | | |
| Thickness | 5 | 5 | 1 | 10 | 15 | 5 | 5 | 5 | 5 | 5 | 5 | 5 |
| of protective | | | | | | | | | | | | |
| layer (μm) | | | | | | | | | | | | |
| Thickness of | — | — | — | — | — | — | — | — | 10 | 1 | — | — |
| pressure-sensitive | | | | | | | | | | | | |
| adhesive layer | | | | | | | | | | | | |
| or adhesive | | | | | | | | | | | | |
| layer (μm) | | | | | | | | | | | | |
| Smoothness (nm) | 5 | 5 | 2 | 8 | 12 | 5 | 5 | 5 | 15 | 7 | 5 | 5 |
| Pencil hardness | B | C | B | C | D | B | B | C | C | B | B | C |
| Anti-scattering | A | A | C | A | A | B | A | A | B | B | A | A |
| properties | | | | | | | | | | | | |
| Scratch resistance | B | B | B | B | B | A | A | A | C | C | B | B |
| Bend resistance | A | A | A | A | A | A | A | A | A | A | A | A |

Tables 6 and 7 also show hydrogen-bonding proton values and (meth)acryloyl values of the polymerizable compounds used in Examples 1 to 4, 7 to 11, 13, and 14, and Comparative Examples 2 to 5. The hydrogen-bonding proton value and the (meth)acryloyl value are shown with regard to (SQ2) in Examples 1 to 3, (A-1) in Examples 4, 7 to 11, 13, and 14, DPCA-20 in Comparative Examples 2, 3, and 5, and DPCA-120 in Comparative Example 4.

As shown in Tables 6 and 7, the samples of Examples 1 to 16 were excellent in smoothness, pencil hardness, and anti-scattering properties.

According to the present invention, it is possible to provide a protective layer which can be used for a foldable device having a cover window made of glass and has excellent smoothness, pencil hardness, and anti-scattering properties, and a foldable device including the protective layer.

The present invention has been described in detail with reference to specific embodiments. To those skilled in the art, it is obvious that various changes or modifications can be added without departing from the gist and scope of the present invention.

The present application is based on Japanese Patent Application (JP2021-062153) filed on Mar. 31, 2021 and Japanese Patent Application (JP2021-205521) filed on Dec. 17, 2021, and the contents of which are incorporated herein by reference.

### EXPLANATION OF REFERENCES

1: glass substrate
2: protective layer
3: scratch resistant layer
4: pressure-sensitive adhesive layer or adhesive layer
5: polyethylene terephthalate (PET) substrate
10: samples of Examples 1 to 9, 15, and 16, and Comparative Examples 4 and 5
20: samples of Examples 10 to 12
30: samples of Examples 13 and 14
40: sample of Comparative Example 1
50: samples of Comparative Examples 2 and 3

What is claimed is:

1. A protective layer to be used in a foldable device having a cover window containing glass, the protective layer comprising:
at least one of the following (A), (B), or (C),
(A) a polymerized substance of a polymerizable compound which has one or more hydrogen bonding group and three or more (meth)acryloyl groups in a molecule of the polymerizable compound, in which a hydrogen-bonding proton value is 3.5 mol/kg or more and a (meth)acryloyl value is 4.8 mol/kg or more,
(B) a compound including a metal coordinate bond,
(C) a compound including a host-guest binding.

2. The protective layer according to claim 1,
wherein an elastic modulus of the protective layer is 6 GPa or more, and
a breaking elongation of the protective layer is 10% or more.

3. The protective layer according to claim 2,
wherein the breaking elongation of the protective layer is 23% or more.

4. The protective layer according to claim 1,
wherein a thickness of the cover window is 100 μm or less.

5. The protective layer according to claim 2,
wherein a thickness of the cover window is 100 μm or less.

6. The protective layer according to claim 3,
wherein a thickness of the cover window is 100 μm or less.

7. The protective layer according to claim 1,
wherein the protective layer contains the polymerized substance (A), and
the hydrogen bonding group in the polymerized substance (A) is at least one selected from the group consisting of a hydroxy group, a carboxy group, a urethane group, an amino group, an amide group, a urea group, a boronic acid group, a thiourethane group, a thioamide group, and a thiourea group.

8. The protective layer according to claim 2,
wherein the protective layer contains the polymerized substance (A), and
the hydrogen bonding group in the polymerized substance (A) is at least one selected from the group consisting of a hydroxy group, a carboxy group, a urethane group, an amino group, an amide group, a urea group, a boronic acid group, a thiourethane group, a thioamide group, and a thiourea group.

9. The protective layer according to claim 3,
wherein the protective layer contains the polymerized substance (A), and
the hydrogen bonding group in the polymerized substance (A) is at least one selected from the group consisting of a hydroxy group, a carboxy group, a urethane group, an amino group, an amide group, a urea group, a boronic acid group, a thiourethane group, a thioamide group, and a thiourea group.

10. The protective layer according to claim 4,
wherein the protective layer contains the polymerized substance (A), and
the hydrogen bonding group in the polymerized substance (A) is at least one selected from the group consisting of a hydroxy group, a carboxy group, a urethane group, an amino group, an amide group, a urea group, a boronic acid group, a thiourethane group, a thioamide group, and a thiourea group.

11. The protective layer according to claim 5,
wherein the protective layer contains the polymerized substance (A), and
the hydrogen bonding group in the polymerized substance (A) is at least one selected from the group consisting of a hydroxy group, a carboxy group, a urethane group, an amino group, an amide group, a urea group, a boronic acid group, a thiourethane group, a thioamide group, and a thiourea group.

12. The protective layer according to claim 1,
wherein a thickness of the protective layer is 10 μm or less.

13. The protective layer according to claim 1,
wherein a pressure-sensitive adhesive layer or an adhesive layer having a thickness of 1 μm or less is provided at at least one surface of the protective layer.

14. The protective layer according to claim 1,
wherein a scratch resistant layer is provided at at least one surface of the protective layer.

15. The protective layer according to claim 14,
wherein the scratch resistant layer comprises at least one of the following (A), (B), or (C),
(A) a polymerized substance of a polymerizable compound which has one or more hydrogen bonding group and three or more (meth)acryloyl groups in a molecule of the polymerizable compound, in which a hydrogen-bonding proton value is 3.5 mol/kg or more and a (meth)acryloyl value is 4.8 mol/kg or more,
(B) a compound including a metal coordinate bond,
(C) a compound including a host-guest binding.

16. A foldable device comprising:
a cover window containing glass; and
a protective layer,
wherein the protective layer is the protective layer according to claim 1.

17. The foldable device according to claim 16,
wherein a thickness of the cover window is 100 μm or less.

18. The foldable device according to claim 16,
wherein a pressure-sensitive adhesive layer or an adhesive layer having a thickness of 1 μm or less is provided between the protective layer and the cover window.

19. The foldable device according to claim 16,
wherein a scratch resistant layer is provided at a surface of the protective layer opposite to a side at which the cover window is provided.

20. The foldable device according to claim 19,
wherein the scratch resistant layer comprises at least one of the following (A), (B), or (C),
(A) a polymerized substance of a polymerizable compound which has one or more hydrogen bonding group and three or more (meth)acryloyl groups in a molecule of the polymerizable compound, in which a hydrogen-bonding proton value is 3.5 mol/kg or more and a (meth)acryloyl value is 4.8 mol/kg or more,
(B) a compound including a metal coordinate bond,
(C) a compound including a host-guest binding.
